(19) United States
(12) Patent Application Publication
(10) Pub. No.: US 2026/0096137 A1
(43) Pub. Date: Apr. 2, 2026

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventors: Kenji AOKI, Kyoto-shi (JP); Takanori OZAWA, Kyoto-shi (JP); Yasunobu HAYASHI, Kyoto-shi (JP); Kohei TOMINAGA, Kyoto-shi (JP); Seigo MORI, Kyoto-shi (JP); Kyo SAKADUME, Kyoto-shi (JP)

(73) Assignee: ROHM CO., LTD., Kyoto-shi (JP)

(21) Appl. No.: 19/411,403

(22) Filed: Dec. 8, 2025

Related U.S. Application Data
(63) Continuation of application No. PCT/JP2024/017697, filed on May 13, 2024.

(30) Foreign Application Priority Data
Jun. 16, 2023 (JP) 2023-099595

(51) Int. Cl. H10D 30/66; H10D 30/01; H10D 62/10; H10D 62/832; H10P 30/20; H10P 30/22

(52) U.S. Cl. CPC H10D 30/662; H10D 30/0291; H10D 30/665; H10D 62/107; H10D 62/127; H10D 62/8325; H10P 30/208; H10P 30/22

(57) ABSTRACT

A semiconductor device includes a chip formed by a wide bandgap semiconductor and having a principal surface on which a semiconductor region of a first conductivity type is formed, a base impurity region of a second conductivity type formed in a surface layer portion of the semiconductor region, a first impurity region formed in a surface layer portion of the base impurity region, and a second impurity region of a conductivity type opposite to that of the first impurity region formed in the surface layer portion of the base impurity region, the second impurity region being adjacent to the first impurity region in a first direction, wherein the second impurity region is formed in a band shape extending in a second direction orthogonal to the first direction, and includes a projection portion selectively protruding toward the first impurity region in the first direction.

### CROSS-REFERENCE TO RELATED APPLICATIONS

The present application is a continuation application of PCT Application No. PCT/JP2024/017697, filed on May 13, 2024, which corresponds to Japanese Patent Application No. 2023-099595 filed on Jun. 16, 2023 in the Japan Patent Office, and the entire disclosure of this application is incorporated herein by reference.

### TECHNICAL FIELD

The present disclosure relates to a semiconductor device and a manufacturing method therefor.

### BACKGROUND ART

Japanese Patent Application Publication No. 2015-207588 discloses an SiC semiconductor device including a plurality of p-type body regions formed on a front surface portion of an n⁻ type SiC semiconductor layer, each of the p-type body regions constituting a unit cell, an n-type source region formed inside the p-type body region, a gate electrode facing the p-type body region through a gate insulating film, an n⁺ type drain region and a p⁺ type collector region formed adjacent to each other on a rear surface portion of the SiC semiconductor layer, and an n⁻ type drift region between the p-type body region and the n⁺ type drain region, in which the p⁺ type collector region is formed such as to cover a region including at least two unit cells in an X-axis along a front surface of the SiC semiconductor layer.

### BRIEF DESCRIPTION OF THE DRAWINGS

FIG. 1 is a plan view illustrating a semiconductor device according to one preferred embodiment.

FIG. 2 is a cross-sectional view taken along line II-II shown in FIG. 1.

FIG. 3 is a plan view illustrating a layout example of a first principal surface.

FIG. 4 is an enlarged plan view illustrating a main portion of the first principal surface.

FIG. 5 is an enlarged plan view illustrating a further main portion of the first principal surface.

FIG. 6 is an enlarged plan view illustrating a main portion of FIG. 5.

FIG. 7 is a cross-sectional view taken along line VII-VII shown in FIG. 5.

FIG. 8 is a cross-sectional view taken along line VIII-VIII shown in FIG. 5.

FIG. 9 is a cross-sectional view taken along line IX-IX shown in FIG. 5.

FIG. 10 is a cross-sectional view taken along line X-X shown in FIG. 5.

FIG. 11 is a schematic view illustrating a wafer.

FIGS. 12A to 12P are cross-sectional views illustrating a method for manufacturing the semiconductor device.

FIG. 13 is a view illustrating a planar pattern of a first mask illustrated in FIG. 12G.

FIG. 14 is a cross-sectional view illustrating a modification example of a source region and a body contact region in FIG. 6.

FIG. 15 is a view illustrating a first modification example of the body contact region.

FIG. 16 is a view illustrating a second modification example of the body contact region.

FIG. 17 is a view illustrating a third modification example of the body contact region.

FIG. 18 is a view illustrating a fourth modification example of the body contact region.

FIG. 19 is a view illustrating a fifth modification example of the body contact region.

### DESCRIPTION OF EMBODIMENTS

Hereinafter, preferred embodiments shall be described in detail with reference to attached drawings. The attached drawings are all schematic views and are not strictly illustrated, and relative positional relationships, scales, proportions, angles, etc., thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially” is used in this description, the wording includes a numerical value (mode) equal to a numerical value (mode) of a comparison target and also includes numerical errors (mode errors) in a range of ±10% on a basis of the numerical value (mode) of the comparison target. Although the wordings “first,” “second,” “third,” etc., are used in the following description, these are symbols attached to names of respective structures in order to clarify the order of description and are not attached with an intention of restricting the names of the respective structures.

In the following description, a conductivity type of a semiconductor (an impurity) is indicated using “p-type” or “n-type” and the “p-type” may be referred to as a “first conductivity type” and the “n-type” may be referred to as a “second conductivity type.” As a matter of course, the “n-type” may be referred to as the “first conductivity type” and the “p-type” may be referred to as the “second conductivity type” instead. The “p-type” is a conductivity type due to a trivalent element and the “n-type” is a conductivity type due to a pentavalent element. The trivalent element is at least one type among boron, aluminum, gallium, and indium. The pentavalent element is at least one type among nitrogen, phosphorus, arsenic, antimony, and bismuth.

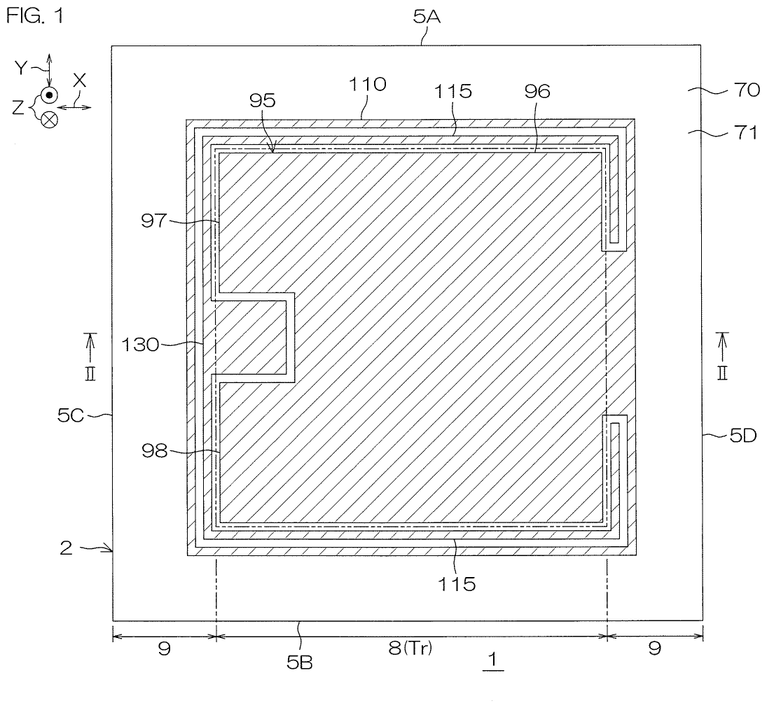

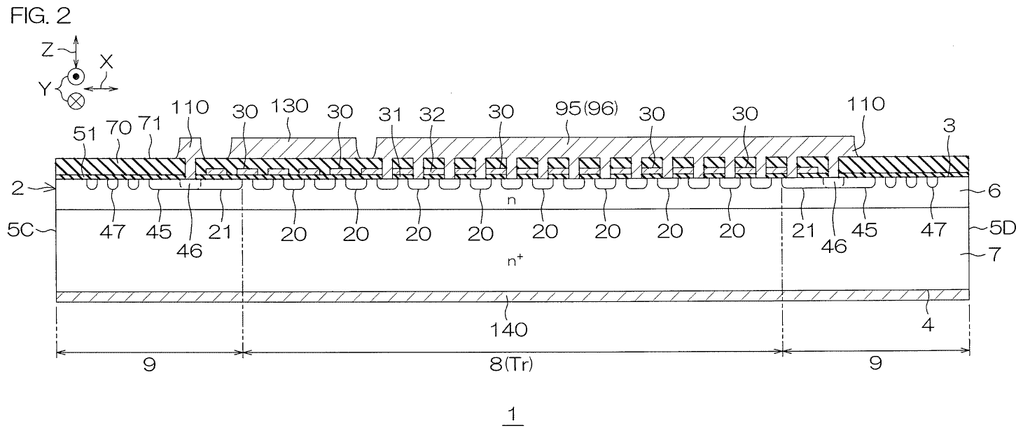

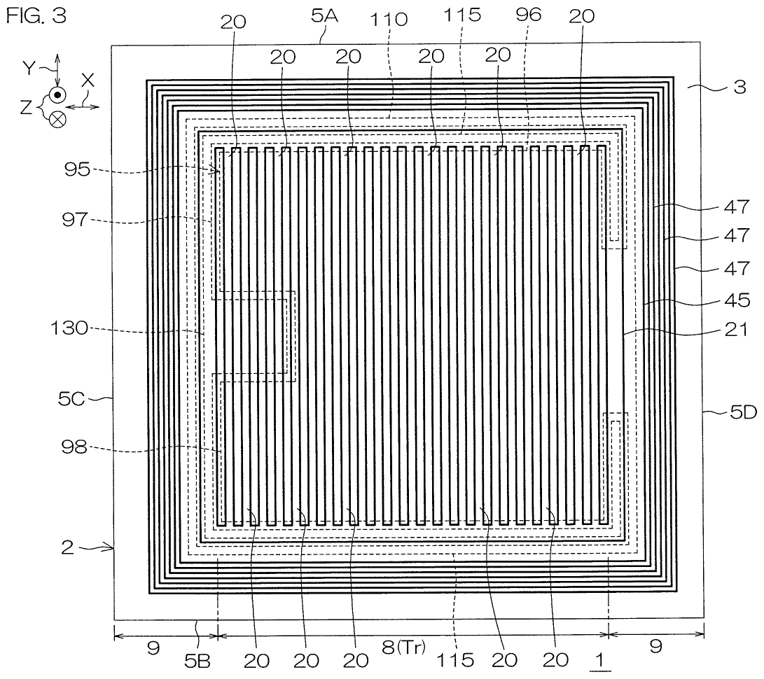

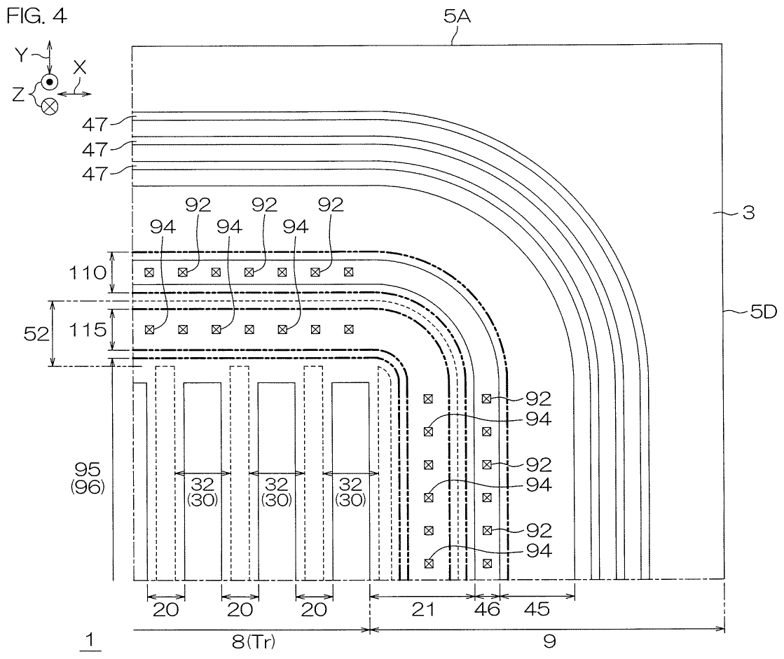

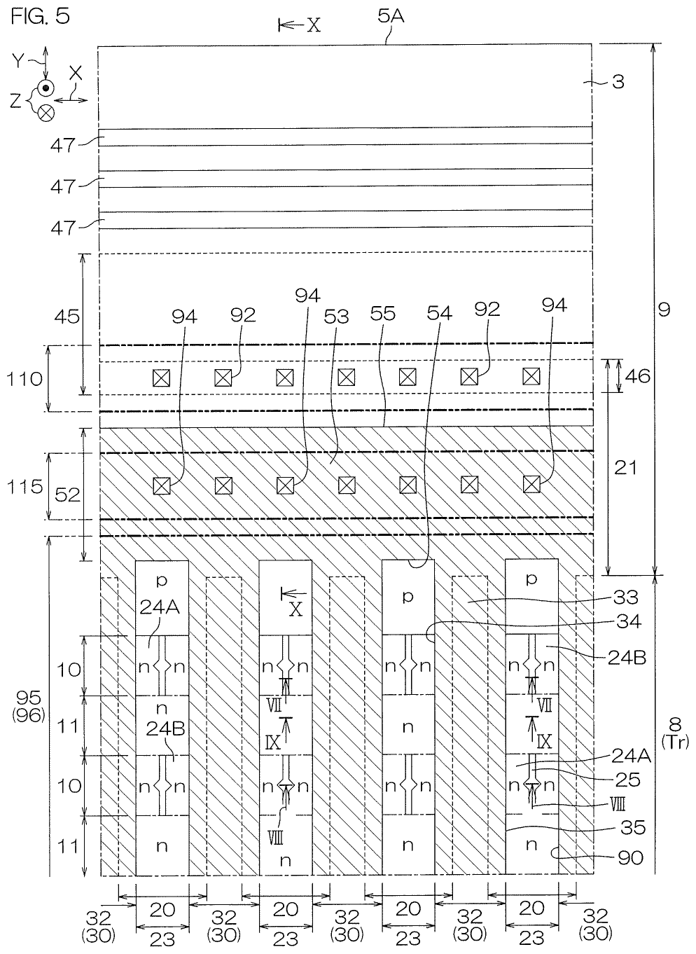

FIG. 1 is a plan view illustrating a semiconductor device 1 according to one preferred embodiment. FIG. 2 is a cross-sectional view taken along line II-II shown in FIG. 1. FIG. 3 is a plan view illustrating a layout example of a first principal surface 3. FIG. 4 is an enlarged plan view illustrating a main portion of the first principal surface 3. FIG. 5 is an enlarged plan view illustrating a further main portion of the first principal surface 3.

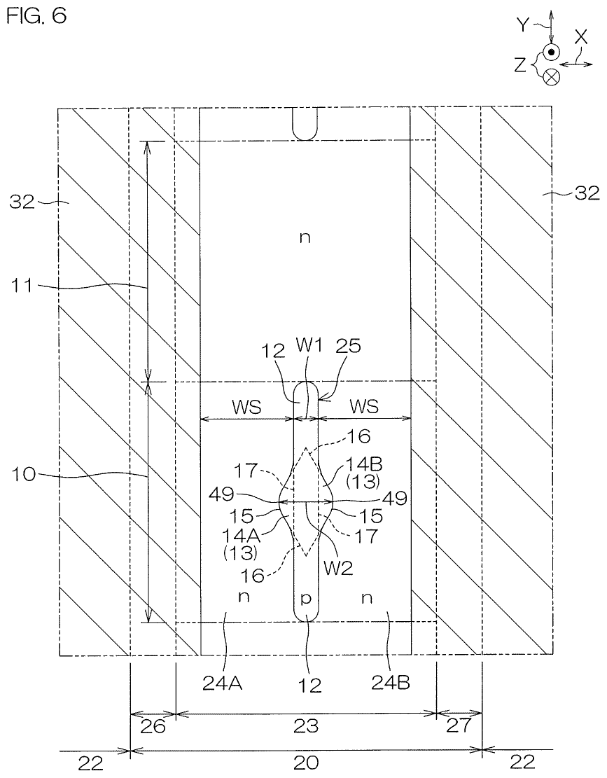

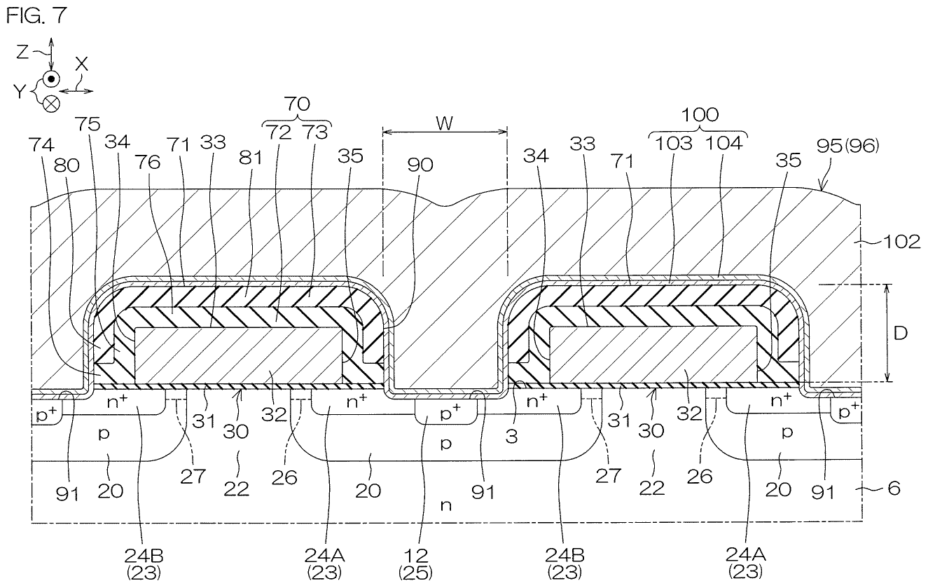

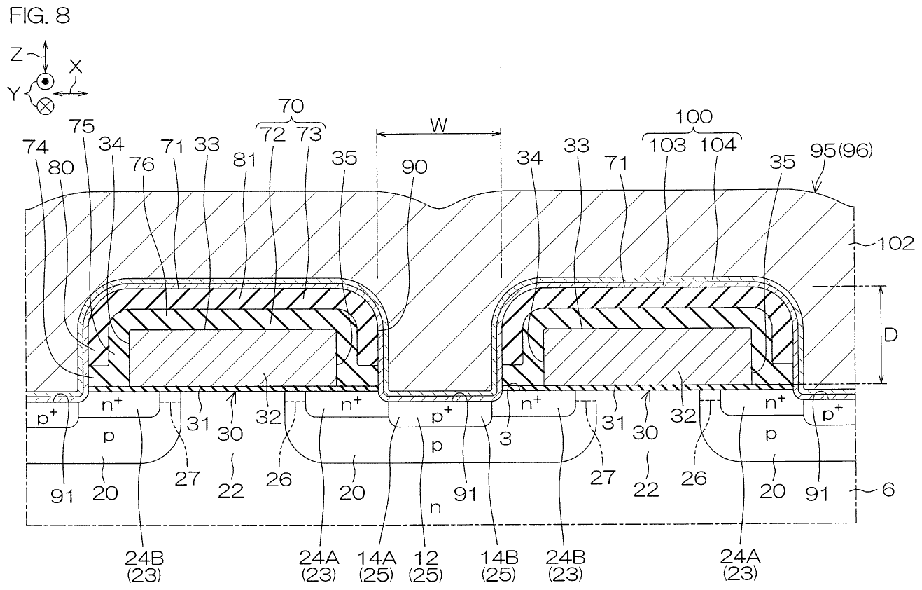

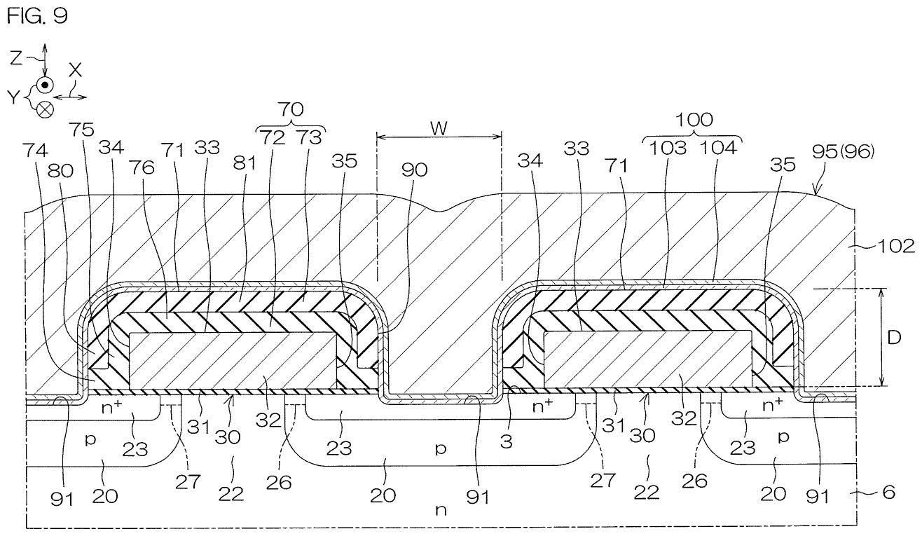

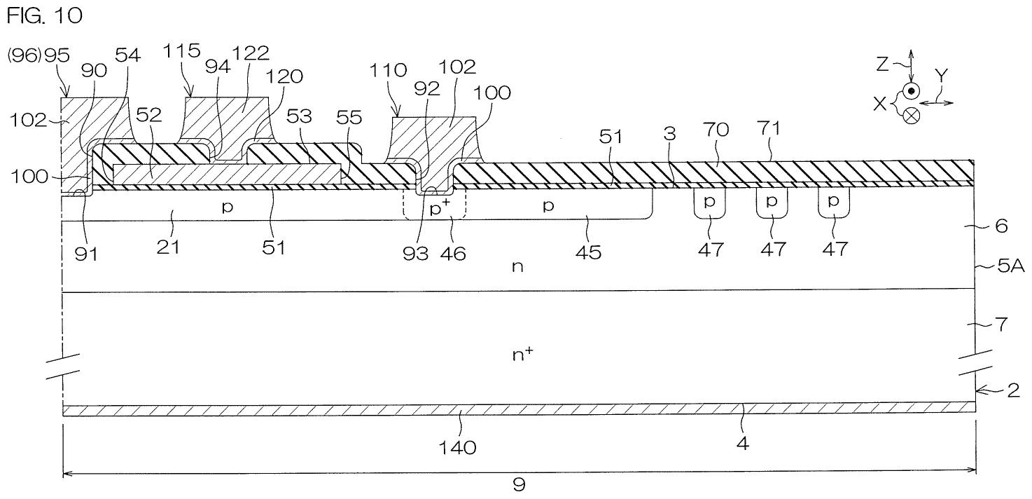

FIG. 6 is an enlarged plan view illustrating a main portion of FIG. 5. FIG. 7 is a cross-sectional view taken along line VII-VII shown in FIG. 5. FIG. 8 is a cross-sectional view taken along line VIII-VIII shown in FIG. 5. FIG. 9 is a cross-sectional view taken along line IX-IX shown in FIG. 5. FIG. 10 is a cross-sectional view taken along line X-X shown in FIG. 5.

Referring to FIGS. 1 to 10, the semiconductor device 1 is a semiconductor switching device having an insulated gate transistor structure Tr as an example of a device structure. The transistor structure Tr has a vertical structure. The semiconductor device 1 is an SiC semiconductor device having a chip 2 containing an SiC monocrystal. The chip 2 may be referred to as an “SiC chip” or as a “semiconductor chip.”

In this embodiment, the chip 2 is constituted of the SiC monocrystal, which is a hexagonal crystal, and is formed in a rectangular parallelepiped shape. The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is to be given, but the chip 2 may be constituted of another polytype instead.

The chip 2 has the first principal surface 3 on one side, a second principal surface 4 on another side, and first to fourth side surfaces 5A to 5D connecting the first principal surface 3 and the second principal surface 4. In plan view as viewed from a vertical direction Z (hereinafter referred to simply as “plan view”), the first principal surface 3 and the second principal surface 4 are each formed in a quadrangular shape. The vertical direction Z is also a thickness direction of the chip 2 and a normal direction to the first principal surface 3 (second principal surface 4). The first principal surface 3 and the second principal surface 4 may be formed in a square shape or a rectangular shape in plan view.

The first principal surface 3 and the second principal surface 4 are preferably formed by c-planes of the SiC monocrystal. In this case, preferably, the first principal surface 3 is formed by a silicon plane ((0001) plane) of the SiC monocrystal and the second principal surface 4 is formed by a carbon plane ((000-1) plane) of the SiC monocrystal.

The first side surface 5A and the second side surface 5B extend in a first direction X along the first principal surface 3 and face each other in a second direction Y intersecting the first direction X along the first principal surface 3. Specifically, the second direction Y is orthogonal to the first direction X. The third side surface 5C and the fourth side surface 5D extend in the second direction Y and face each other in the first direction X.

In the following description, one side in the first direction X means the third side surface 5C side, and the other side in the first direction X means the fourth side surface 5D side. Also, one side in the second direction Y means the first side surface 5A side, and the other side in the second direction Y means the second side surface 5B side. In this embodiment, the first direction X is an m-axis direction ([1-100] direction) of the SiC monocrystal and the second direction Y is an a-axis direction ([11-20] direction) of the SiC monocrystal. As a matter of course, the first direction X may instead be the a-axis direction of the SiC monocrystal and the second direction Y may instead be the m-axis direction of the SiC monocrystal.

The chip 2 (the first principal surface 3 and the second principal surface 4) has an off angle inclined at a predetermined angle in a predetermined off direction with respect to the c-plane of the SiC monocrystal. That is, a c-axis ((0001) axis) of the SiC monocrystal is inclined by just the off angle toward the off direction from the vertical axis. Also, the c-plane of the SiC monocrystal is inclined by just the off angle with respect to the horizontal plane.

The off direction is preferably the a-axis direction (that is, the second direction Y) of the SiC monocrystal. The off angle may exceed 0° and be 10° or less. The off angle may have a value belonging to at least one range among exceeding 0° and being 1° or less, being 1° or more and 2.5° or less, being 2.5° or more and 5° or less, being 5° or more and 7.5° or less, and being 7.5° or more and 10° or less.

The off angle is preferably 5° or less. The off angle is particularly preferably 2° or more and 4.5° or less. The off angle is typically set in a range of 4°±0.1°. This description does not exclude an embodiment in which the off angle is 0° (that is, an embodiment in which the first principal surface 3 is a just surface with respect to the c-plane).

The semiconductor device 1 includes a first semiconductor region 6 of the n-type that is formed in a region (surface layer portion) inside the chip 2 at the first principal surface 3 side. The first semiconductor region 6 may be referred to as a “drift region,” a “drain drift region,” a “drain region,” etc. A drain potential as a high potential (first potential) is applied to the first semiconductor region 6. The first semiconductor region 6 is formed in a layer shape extending along the first principal surface 3 and is exposed from the first principal surface 3 and the first to fourth side surfaces 5A to 5D. In this embodiment, the first semiconductor region 6 consists of an epitaxial layer (specifically, an SiC epitaxial layer).

The semiconductor device 1 includes a second semiconductor region 7 of the n-type that is formed in a region (surface layer portion) inside the chip 2 at the second principal surface 4 side. A drain potential is applied to the second semiconductor region 7. The second semiconductor region 7 may be referred to as a “drain region,” etc. The second semiconductor region 7 has an n-type impurity concentration higher than that of the first semiconductor region 6 and is electrically connected to the first semiconductor region 6 inside the chip 2.

The second semiconductor region 7 is formed in a layer shape extending along the second principal surface 4 and is exposed from the second principal surface 4 and the first to fourth side surfaces 5A to 5D. In this embodiment, the second semiconductor region 7 consists of a semiconductor substrate (specifically, an SiC substrate). That is, the chip 2 has a laminated structure including the semiconductor substrate and the epitaxial layer. The second semiconductor region 7 has a thickness larger than the thickness of the first semiconductor region 6.

The semiconductor device 1 includes an active region 8 that is set in the chip 2. The active region 8 is a region that includes a device structure (transistor structure Tr) and in which an output current (drain current) is generated. The active region 8 is set in an inner portion of the chip 2 at intervals from peripheral edges (the first to fourth side surfaces 5A to 5D) of the chip 2 in plan view. The active region 8 is set in a polygonal shape (in this embodiment, a quadrangular shape) having four sides parallel to the peripheral edges of the chip 2 in plan view. A plane area of the active region 8 is preferably 50% or more and 90% or less of the plane area of the first principal surface 3.

The semiconductor device 1 includes an outer peripheral region 9 that, in the chip 2, is set outside the active region 8. The outer peripheral region 9 is provided in a region between the peripheral edges of the chip 2 and the active region 8 in plan view. The outer peripheral region 9 extends in a band shape along the active region 8 and is set to a polygonal annular shape (in this embodiment, a quadrangular annular shape) that surrounds the active region 8 in plan view.

The semiconductor device 1 includes a plurality of p-type body regions 20 formed in a surface layer portion of the first principal surface 3 in the active region 8. A source potential as a low potential (second potential) different from a high potential (first potential) is applied to the plurality of body regions 20. The plurality of body regions 20 are arranged at intervals in the first direction X, and are each formed in a band shape extending in the second direction Y. That is, the plurality of body regions 20 are arranged in a stripe shape extending in the second direction Y.

The plurality of body regions 20 are formed at intervals from a bottom portion of the first semiconductor region 6 toward the first principal surface 3, and face the second semiconductor region 7 across a part of the first semiconductor region 6. The plurality of body regions 20 are preferably formed at intervals from an intermediate portion of the first semiconductor region 6 toward the first principal surface 3. The plurality of body regions 20 are exposed from the first principal surface 3.

The semiconductor device 1 includes a p-type outer body region 21 formed in the surface layer portion of the first principal surface 3 in the outer peripheral region 9. The outer body region 21 preferably has a p-type impurity concentration substantially equal to the p-type impurity concentration of the body region 20. As a matter of course, the p-type impurity concentration of the outer body region 21 may be less than the p-type impurity concentration of the body region 20, or may be higher than the p-type impurity concentration of the body region 20.

The outer body region 21 is formed at intervals from the peripheral edges (the first to fourth side surfaces 5A to 5D) of the first principal surface 3 toward the active region 8, and extends in a band shape along the active region 8. The outer body region 21 has a portion extending in a band shape in the first direction X and a portion extending in a band shape in the second direction Y in plan view, and demarcates the active region 8 from a plurality of directions.

In this embodiment, the outer body region 21 surrounds the active region 8 in plan view and is demarcated in a polygonal annular shape (in this embodiment, a quadrangular annular shape) having four sides parallel to the peripheral edges of the first principal surface 3. That is, the outer body region 21 forms a boundary portion between the active region 8 and the outer peripheral region 9. The outer body region 21 may have an edge portion connecting the portion extending in the first direction X and the portion extending in the second direction Y in plan view in an arcuate shape (preferably a quadrant arcuate shape) (see FIG. 4).

The outer body region 21 has an inner edge portion on the active region 8 side and an outer edge portion on the peripheral edge side of the first principal surface 3. The inner edge portion of the outer body region 21 is connected to the plurality of body regions 20 in the portion extending in the first direction X. Thus, the outer body region 21 is fixed at the same potential as the plurality of body regions 20.

The outer body region 21 preferably has a width larger than the width of the body region 20. The width of the body region 20 is a width in a direction orthogonal to an extension direction (that is, the first direction X). The width of the outer body region 21 is a width in a direction orthogonal to the extension direction. As a matter of course, the width of the outer body region 21 may be substantially equal to the width of the body region 20, or may be less than the thickness of the body region 20.

The ratio of the width of the outer body region 21 to the width of the body region 20 may be 10 or more and 50 or less. The width ratio is preferably 20 or more and 40 or less.

The outer body region 21 is formed at an interval from the bottom portion of the first semiconductor region 6 toward the first principal surface 3, and faces the second semiconductor region 7 across a part of the first semiconductor region 6. The outer body region 21 is preferably formed at an interval from the intermediate portion of the first semiconductor region 6 toward the first principal surface 3. The outer body region 21 is exposed from the first principal surface 3.

The outer body region 21 preferably has a thickness (depth) substantially equal to the thickness (depth) of the body region 20. As a matter of course, the thickness of the outer body region 21 may be less than the thickness of the body region 20, or may be larger than the thickness of the body region 20.

Referring to FIGS. 6 to 9, the semiconductor device 1 includes a plurality of n-type surface layer drift regions 22 formed in the surface layer portion of the first principal surface 3. In this embodiment, each of the plurality of surface layer drift regions 22 is constituted of a part of the first semiconductor region 6. As a matter of course, the plurality of surface layer drift regions 22 may have an n-type impurity concentration higher than the n-type impurity concentration of the first semiconductor region 6, or may have an n-type impurity concentration lower than the n-type impurity concentration of the first semiconductor region 6.

The plurality of surface layer drift regions 22 are each demarcated in a region between the plurality of body regions 20 adjacent to each other in the first direction X. Specifically, the plurality of surface layer drift regions 22 are each demarcated by the plurality of body regions 20 and the outer body region 21 in the surface layer portion of the first principal surface 3. The plurality of surface layer drift regions 22 are arranged at intervals in the first direction X, and are each formed in a band shape extending in the second direction Y. That is, the plurality of surface layer drift regions 22 are formed in a stripe shape extending in the second direction Y.

The semiconductor device 1 includes an n-type source region 23 formed in surface layer portions of the plurality of body regions 20, respectively. The source region 23 has an n-type impurity concentration higher than the n-type impurity concentration of the first semiconductor region 6. A source potential is applied to the source region 23.

The semiconductor device 1 includes a plurality of p-type contact regions 25 each formed in the surface layer portion of the plurality of body regions 20 in the active region 8. The contact region 25 may be referred to as a “back gate region.” A source potential is applied to the plurality of contact regions 25. The contact region 25 has a p-type impurity concentration higher than the p-type impurity concentration of the body region 20.

Referring to FIGS. 5 and 6, each body region 20 includes a plurality of first sections 10 and a plurality of second sections 11 alternately in the second direction Y. A clear boundary does not have to be formed between the first section 10 and the second section 11. In FIGS. 5 and 6, the boundary between the first section 10 and the second section 11 is indicated by an alternate long and short dashed line for clarity. As illustrated in FIGS. 5 and 6, the first section 10 and the second section 11 may have the same length in the second direction Y, or may have different lengths in the second direction Y. For example, in the second direction Y, the first section 10 may be longer than the second section 11, or the first section 10 may be shorter than the second section 11.

The plurality of contact regions 25 are arranged at intervals for each first section 10 such as to skip each second section 11 in the second direction Y. In the body region 20, the contact region 25 and regions on both sides of the contact region 25 in the first direction X may be the first section 10. The second section 11 may be a region between the plurality of contact regions 25 adjacent to each other in the second direction Y.

Each contact region 25 extends in a band shape along the extension direction of the body region 20 (second direction Y). The contact region 25 is formed at an interval from the outer body region 21 in the second direction Y. That is, the contact region 25 is not formed in the outer body region 21. The contact region 25 is formed at an interval from a bottom portion of the body region 20 toward the first principal surface 3, and faces the first semiconductor region 6 across a part of the body region 20. Each contact region 25 is formed at an interval from both peripheral edges on one side and the other side of the body region 20 in the first direction X. In this embodiment, the contact region 25 is formed in a central portion of the body region 20 in the first direction X.

By forming the contact region 25, the source region 23 is separated into a plurality of source regions 24A and 24B in the first section 10. In other words, one contact region 25 is interposed in a region between the first source region 24A and the second source region 24B in the surface layer portion of the corresponding body region 20. Each contact region 25 is sandwiched between the first source region 24A and the second source region 24B in the first direction X.

The plurality of source regions 24A and 24B include a first source region 24A positioned on one side in the first direction X and a second source region 24B positioned on the other side in the first direction X in the surface layer portion of each body region 20. In this embodiment, in the first direction X, one first source region 24A is formed on one end side of the body region 20, and one second source region 24B is formed on the other end side of the body region 20.

The first source region 24A is formed at an interval from one end of the body region 20 toward the other end, and extends in a band shape along the extension direction of the body region 20. The first source region 24A is formed at an interval from the bottom portion of the body region 20 toward the first principal surface 3, and faces the first semiconductor region 6 across a part of the body region 20.

The second source region 24B is formed at an interval from the first source region 24A toward the other end of the body region 20. The second source region 24B is formed at an interval from the other end of the body region 20 toward the one end, and extends in a band shape along the extension direction of the body region 20. The second source region 24B is formed at an interval from the bottom portion of the body region 20 toward the first principal surface 3, and faces the first semiconductor region 6 across a part of the body region 20.

Referring to FIG. 6, the contact region 25 includes a first portion 12 extending in a band shape in the second direction Y and a plurality of projection portions 13 protruding outward in the first direction X from the first portion 12.

The first portion 12 crosses the first section 10 of the body region 20 in the second direction Y, and has an end portion at a boundary position between the first section 10 and the second section 11. The first portion 12 may be referred to by another name according to its planar shape. For example, as illustrated in FIG. 6, when a shape assumed by excluding the projection portion 13 (a shape in which portions vertically facing each other across the projection portion 13 in the second direction Y are connected by a broken line 17) is a band shape in plan view, the first portion 12 may be referred to as a band-shaped portion. A width (first width W1) of the first portion 12 may be, for example, 0.2 μm or more and 0.6 μm or less. The first width W1 may be constant or substantially constant in the second direction Y.

In this embodiment, the plurality of projection portions 13 may include a pair of projection portions 14A and 14B protruding from a center of the first portion 12 in the second direction Y toward both sides in the first direction X. That is, one projection portion 13 is formed on each of one side and the other side of the first portion 12 in the first direction X. In this embodiment, the projection portion 13 protruding toward the first source region 24A is a first projection portion 14A, and the projection portion 13 protruding toward the second source region 24B is a second projection portion 14B. The first projection portion 14A and the second projection portion 14B protrude from the same position of the first portion 12 toward the opposite sides.

Each of the projection portions 14A and 14B may have a polygonal shape in plan view protruding with respect to the first portion 12 and having one or a plurality of apex portions 49. In this embodiment, each of the projection portions 14A and 14B is formed in a triangular shape in plan view. In the contact region 25, the apex portion 49 has a rounded round shape.

The pair of projection portions 14A and 14B may have an overall shape of a rhombus or a circle that protrudes evenly toward both sides with respect to the first portion 12 in plan view. The overall shape of the pair of projection portions 14A and 14B may be a shape defined by an outline 15 of the pair of projection portions 14A and 14B and an inner extension line 16 (virtual line) of the outline 15 toward the inner side of the contact region 25 (first portion 12). FIG. 6 illustrates a pattern in which the overall shape of the pair of projection portions 14A and 14B is a rhombus. In this embodiment, an overall width (second width W2) of the pair of projection portions 14A and 14B from an end portion in the first direction X of the first projection portion 14A to an end portion in the first direction X of the second projection portion 14B may be 1.2 μm or more and 1.6 μm or less.

In addition, in this embodiment, a width WS of each of the first source region 24A and the second source region 24B on both sides of the first portion 12 in the first direction X may be larger than the overall width (second width W2) of the pair of projection portions 14A and 14B. The width WS may be, for example, 2 μm or more and 4 μm or less.

The semiconductor device 1 includes a plurality of p-type channel regions 26 and 27 formed in the surface layer portion of the first principal surface 3. The plurality of channel regions 26 and 27 are demarcated in regions between end portions of the plurality of body regions 20 (the plurality of surface layer drift regions 22) and peripheral edges of the source region 23, respectively, in the surface layer portions of the plurality of body regions 20. In this embodiment, the plurality of channel regions 26 and 27 are arranged at intervals in the first direction X and are each formed in a band shape extending in the second direction Y. That is, the plurality of channel regions 26 and 27 are arranged in a stripe shape extending in the second direction Y.

The plurality of channel regions 26 and 27 include a plurality of first channel regions 26 and a plurality of second channel regions 27. The plurality of first channel regions 26 are formed in a region on the side of the plurality of first source regions 24A, and form a current path extending in a horizontal direction. The plurality of second channel regions 27 are formed in a region on the side of the plurality of second source regions 24B, and form a current path extending in the horizontal direction.

The semiconductor device 1 includes a plurality of gate structures 30 of a planar electrode type disposed on the first principal surface 3 in the active region 8. The plurality of gate structures 30 are arranged at intervals in the first direction X, and are each formed in a band shape extending in the second direction Y. That is, the plurality of gate structures 30 are arranged in a stripe shape extending in the second direction Y. The extension direction of the plurality of gate structures 30 coincides with the off direction of the SiC monocrystal.

Each gate structure 30 is disposed on at least one channel region 26 or 27. In this embodiment, each gate structure 30 is disposed such as to extend across two body regions 20 adjacent to each other across one surface layer drift region 22, and covers the plurality of channel regions 26 and 27. Specifically, each gate structure 30 is disposed such as to extend across the source region 23 on one body region 20 side and the source region 23 on the other body region 20 side, and covers the surface layer drift region 22, the source region 23 (the first source region 24A and the second source region 24B), the first channel region 26, and the second channel region 27.

Hereinafter, a configuration of one gate structure 30 shall be described. The gate structure 30 has a laminated structure including an insulating film 31 and a gate electrode 32. The gate structure 30 does not have an insulating side wall structure (spacer) at a side of the gate electrode 32. The insulating film 31 may include at least one among a silicon oxide film, a silicon nitride film, and a silicon oxynitride film. In this embodiment, the insulating film 31 has a single layer structure constituted of the silicon oxide film. The insulating film 31 particularly preferably includes a silicon oxide film constituted of an oxide of the chip 2.

The insulating film 31 covers the first principal surface 3 in a film shape and is disposed on at least one channel region 26 or 27. In this embodiment, the insulating film 31 is disposed such as to extend across two body regions 20 adjacent to each other across one surface layer drift region 22, and covers the plurality of channel regions 26 and 27.

Specifically, the insulating film 31 is disposed such as to extend across the source region 23 on one body region 20 side and the source region 23 on the other body region 20 side, and covers the surface layer drift region 22, the source region 23 (the first source region 24A and the second source region 24B), the first channel region 26, and the second channel region 27.

In the first section 10, the insulating film 31 partially covers the first source region 24A at an interval from the contact region 25, and exposes a part of the first source region 24A and the contact region 25 from the first principal surface 3. In the first section 10, the insulating film 31 partially covers the second source region 24B at an interval from the contact region 25, and exposes a part of the second source region 24B and the contact region 25 from the first principal surface 3. In the second section 11, the insulating film 31 partially covers the source region 23 and exposes a part of the source region 23 from the first principal surface 3.

A thickness of the insulating film 31 may be 10 nm or more and 150 nm or less. The thickness of the insulating film 31 may have a value belonging to at least one range among 10 nm or more and 25 nm or less, 25 nm or more and 50 nm or less, 50 nm or more and 75 nm or less, 75 nm or more and 100 nm or less, 100 nm or more and 125 nm or less, and 125 nm or more and 150 nm or less. The thickness of the insulating film 31 is preferably 25 nm or more and 75 nm or less.

The gate electrode 32 is disposed on the insulating film 31 and faces at least one channel region 26 or 27 across the insulating film 31. A gate potential as a control potential is applied to the gate electrode 32. The gate electrode 32 controls inversion and non-inversion of at least one channel region 26 or 27 in response to the gate potential.

The gate electrode 32 contains a semiconductor polycrystal having conductivity. The gate electrode 32 may contain either or both of a p-type conductive polysilicon and an n-type conductive polysilicon. The conductivity type of the gate electrode 32 is adjusted according to the gate threshold voltage to be achieved. The gate electrode 32 may be referred to as a “polysilicon gate,” a “poly gate,” etc.

The gate electrode 32 is formed in a band shape extending in the second direction Y. That is, the extension direction of the gate electrode 32 coincides with the off direction of the SiC monocrystal. In this embodiment, the gate electrode 32 is formed at intervals inward from both end portions of the insulating film 31 in the first direction X, and exposes both end portions of the insulating film 31. The gate electrode 32 is disposed on the insulating film 31 such as to extend across two body regions 20 adjacent to each other across one surface layer drift region 22, and faces the plurality of channel regions 26 and 27 across the insulating film 31.

Specifically, the gate electrode 32 is disposed such as to extend across the source region 23 on one body region 20 side and the source region 23 on the other body region 20 side, and faces the surface layer drift region 22, the source region 23 (the first source region 24A and the second source region 24B), the first channel region 26, and the second channel region 27 across the insulating film 31.

The gate electrode 32 includes an electrode surface 33, a first side wall 34 on one side in the first direction X, and a second side wall 35 on the other side in the first direction X. The electrode surface 33 extends along the insulating film 31 (first principal surface 3). The electrode surface 33 may extend substantially parallel to the insulating film 31 (first principal surface 3).

The first side wall 34 is formed at an interval from one end portion toward the other end portion of the insulating film 31 in the first direction X, and extends in the vertical direction Z. The second side wall 35 is formed at an interval from the other end portion toward the one end portion of the insulating film 31 in the first direction X, and extends in the vertical direction Z.

The first side wall 34 and the second side wall 35 may extend perpendicularly to the insulating film 31. That is, the gate electrode 32 may be formed in a quadrangular shape (flat rectangular shape) in cross-sectional view. The first side wall 34 and the second side wall 35 may be inclined obliquely toward the electrode surface 33. That is, the gate electrode 32 may be formed in a tapered shape (preferably an isosceles trapezoidal shape) in cross-sectional view.

A width of the gate structure 30 may be 1 μm or more and 10 μm or less. The width of the gate structure 30 is a width in a direction orthogonal to the extension direction (that is, the first direction X). The width of the gate structure 30 is preferably 1 μm or more and 5 μm or less.

A thickness of the gate structure 30 may be 0.1 μm or more and 2.0 μm or less. The thickness of the gate structure 30 is preferably 0.2 μm or more and 1.0 μm or less.

Referring to FIGS. 4, 5, and 10, the semiconductor device 1 includes a p-type terminal region 45 formed on the first principal surface 3 in the outer peripheral region 9. The terminal region 45, which may be referred to as a “well region,” a “terminal well region,” etc., may have a p-type impurity concentration substantially equal to the p-type impurity concentration of the outer body region 21. The p-type impurity concentration of the terminal region 45 may be higher than the p-type impurity concentration of the outer body region 21, or may be lower than the p-type impurity concentration of the outer body region 21.

The terminal region 45 is formed in a region between the peripheral edges of the first principal surface 3 and the outer body region 21 at intervals inward from the peripheral edges of the first principal surface 3. The terminal region 45 extends in a band shape along the outer body region 21 in plan view. The terminal region 45 has a portion extending in a band shape in the first direction X and a portion extending in a band shape in the second direction Y in plan view, and demarcates the active region 8 from a plurality of directions.

In this embodiment, the terminal region 45 surrounds the outer body region 21 in plan view, and is demarcated in a polygonal annular shape (a quadrangular annular shape in this embodiment) having four sides parallel to the peripheral edges of the first principal surface 3. The terminal region 45 may have an edge portion connecting the portion extending in the first direction X and the portion extending in the second direction Y in plan view in an arcuate shape (preferably a quadrant arcuate shape) (see FIG. 4).

The terminal region 45 is formed at an interval from the bottom portion of the first semiconductor region 6 toward the first principal surface 3, and faces the second semiconductor region 7 across a part of the first semiconductor region 6. The terminal region 45 is preferably formed at an interval from the intermediate portion of the first semiconductor region 6 toward the first principal surface 3. The terminal region 45 may have a thickness (depth) substantially equal to the thickness (depth) of the outer body region 21. The thickness of the terminal region 45 may be larger than the thickness of the outer body region 21, or may be smaller than the thickness of the outer body region 21.

The terminal region 45 has an inner edge portion on the active region 8 side and an outer edge portion on the peripheral edge side of the first principal surface 3. The inner edge portion of the terminal region 45 is connected to the outer edge portion of the outer body region 21. As a result, the terminal region 45 is fixed at the same potential as the outer body region 21, and is electrically connected to the plurality of body regions 20 through the outer body region 21. In this embodiment, the inner edge portion of the terminal region 45 is connected to the outer edge portion of the outer body region 21 over an entire circumference.

The terminal region 45 (inner edge portion) has an overlap region 46 overlapping the outer edge portion of the outer body region 21. The overlap region 46 is a high concentration region including the outer edge portion of the outer body region 21 and the inner edge portion of the terminal region 45. That is, the overlap region 46 includes both the p-type impurity of the outer body region 21 and the p-type impurity of the terminal region 45, and has a p-type impurity concentration higher than both the p-type impurity concentration of the outer body region 21 and the p-type impurity concentration of the terminal region 45.

The overlap region 46 extends in a band shape along the outer body region 21 in plan view. The overlap region 46 has a portion extending in a band shape in the first direction X and a portion extending in a band shape in the second direction Y in plan view, and demarcates the active region 8 from a plurality of directions. In this embodiment, the overlap region 46 is demarcated in a polygonal annular shape (a quadrangular annular shape in this embodiment) having four sides parallel to the peripheral edges of the first principal surface 3. A width of the overlap region 46 is preferably larger than the width of the body region 20. As a matter of course, the width of the overlap region 46 may be not more than the width of the body region 20.

The semiconductor device 1 may have a p-type well region (46) having a relatively high concentration instead of the overlap region 46. In this case, the well region (46) has a p-type impurity concentration higher than both the p-type impurity concentration of the outer body region 21 and the p-type impurity concentration of the terminal region 45. The well region (46) may be formed in either or both of a surface layer portion of the outer body region 21 and a surface layer portion of the terminal region 45.

The semiconductor device 1 includes at least one (preferably, two or more and twenty or less) p-type field region 47 formed in the surface layer portion of the first principal surface 3 in the outer peripheral region 9. The number of the plurality of field regions 47 is typically three or more and eight or less. In this embodiment, the semiconductor device 1 includes three field regions 47. The plurality of field regions 47 are formed in an electrically floating state, and relax an electric field in the chip 2 at a peripheral edge portion of the first principal surface 3. The number, interval, width, depth, p-type impurity concentration, etc., of the field regions 47 are arbitrary, and can take various values according to the electric field to be relaxed.

The field region 47 may have a p-type impurity concentration substantially equal to the p-type impurity concentration of the body region 20 (terminal region 45). The p-type impurity concentration of the field region 47 may be higher than the p-type impurity concentration of the body region 20 (terminal region 45), or may be lower than the p-type impurity concentration of the body region 20 (terminal region 45).

The plurality of field regions 47 are formed in a region between the peripheral edges of the first principal surface 3 and the active region 8 at intervals inward from the peripheral edges of the first principal surface 3. Specifically, the plurality of field regions 47 are formed in a region between the peripheral edges of the first principal surface 3 and the outer body region 21. More specifically, in a region between the peripheral edges of the first principal surface 3 and the terminal region 45, the plurality of field regions 47 are arranged at intervals from the terminal region 45 toward the peripheral edges of the first principal surface 3.

The plurality of field regions 47 are formed in a band shape extending along the active region 8 (terminal region 45) in plan view. Each of the plurality of field regions 47 has a portion extending in a band shape in the first direction X and a portion extending in a band shape in the second direction Y. In this embodiment, the plurality of field regions 47 are formed in a polygonal annular shape (in this embodiment, a quadrangular annular shape) surrounding the active region 8 (terminal region 45) in plan view. The plurality of field regions 47 may have an edge portion connecting the portion extending in the first direction X and the portion extending in the second direction Y in an arcuate shape (preferably a quadrant arcuate shape) (see FIG. 4).

The plurality of field regions 47 are formed at intervals from the bottom portion of the first semiconductor region 6 toward the first principal surface 3, and face the second semiconductor region 7 across a part of the first semiconductor region 6. The plurality of field regions 47 are preferably formed at intervals from the intermediate portion of the first semiconductor region 6 toward the first principal surface 3.

Referring to FIG. 10, the semiconductor device 1 includes an outer peripheral insulating film 51 covering the first principal surface 3 in the outer peripheral region 9. The outer peripheral insulating film 51 may include at least one among a silicon oxide film, a silicon nitride film, and a silicon oxynitride film. In this embodiment, the outer peripheral insulating film 51 has a single layer structure constituted of the silicon oxide film. The outer peripheral insulating film 51 particularly preferably includes a silicon oxide film constituted of an oxide of the chip 2. The outer peripheral insulating film 51 is preferably made of the same kind of insulating material as the insulating material of the insulating film 31. The outer peripheral insulating film 51 preferably has a thickness substantially equal to the thickness of the insulating film 31.

The outer peripheral insulating film 51 covers the first principal surface 3 in a film shape in the outer peripheral region 9. The outer peripheral insulating film 51 collectively covers the outer body region 21, the terminal region 45, and the plurality of field regions 47. The outer peripheral insulating film 51 is connected to the plurality of insulating films 31 on the active region 8 side. Specifically, the outer peripheral insulating film 51 is integrally formed with the plurality of insulating films 31, and forms one insulating film with the plurality of insulating films 31.

Referring to FIGS. 4, 5, and 10, the semiconductor device 1 includes a gate wiring 52 disposed on the first principal surface 3 in the outer peripheral region 9. The semiconductor device 1 does not have an insulating side wall structure (spacer) at a side of the gate wiring 52. The gate wiring 52 is selectively routed on the first principal surface 3 and has a portion extending in a direction different from the plurality of gate electrodes 32. The gate wiring 52 is connected to the plurality of gate electrodes 32, and applies a gate signal to the plurality of gate electrodes 32. The gate wiring 52 may be referred to as a “polysilicon gate wiring,” a “poly gate wiring,” a “second gate electrode,” etc.

The gate wiring 52 contains a semiconductor polycrystal having conductivity. The gate wiring 52 may contain either or both of a p-type conductive polysilicon and an n-type conductive polysilicon. The gate wiring 52 preferably has the same conductivity type as the conductivity type of the gate electrode 32. The conductivity type of the gate wiring 52 is adjusted according to the conductivity type of the gate electrode 32.

The gate wiring 52 is disposed on the outer peripheral insulating film 51 in the outer peripheral region 9. Specifically, the gate wiring 52 is disposed on a portion of the outer peripheral insulating film 51 covering the outer body region 21, and faces the outer body region 21 across the outer peripheral insulating film 51. The gate wiring 52 is formed at intervals from the peripheral edges of the first principal surface 3 toward the active region 8, and extends in a band shape along the active region 8. The gate wiring 52 has a portion extending in a band shape in the first direction X and a portion extending in a band shape in the second direction Y in plan view, and demarcates the active region 8 from a plurality of directions.

In this embodiment, the gate wiring 52 surrounds the active region 8 in plan view, and is demarcated in a polygonal annular shape (a quadrangular annular shape in this embodiment) having four sides parallel to the peripheral edges of the first principal surface 3. The gate wiring 52 may have a shape with ends or an endless shape. In this embodiment, the gate wiring 52 extends in a band shape (an annular shape in this embodiment) along the outer body region 21 in plan view, and faces the outer body region 21 across the outer peripheral insulating film 51 in an entire region in a lamination direction. The gate wiring 52 may have an edge portion connecting the portion extending in the first direction X and the portion extending in the second direction Y in plan view in an arcuate shape (preferably a quadrant arcuate shape) (see FIG. 4).

The gate wiring 52 is formed to be narrower than the outer body region 21 in plan view, and is disposed above the outer body region 21 at intervals from the inner edge portion and the outer edge portion of the outer body region 21. That is, in this embodiment, the plurality of gate electrodes 32 are led out above the outer body region 21, and the gate wiring 52 is connected to the plurality of gate electrodes 32 above the outer body region 21.

A width of the gate wiring 52 is preferably larger than the width of the gate electrode 32. The width of the gate wiring 52 is a width in a direction orthogonal to the extension direction. As a matter of course, the width of the gate wiring 52 may be not more than the width of the gate electrode 32. The width of the gate wiring 52 may be larger than the width of the outer body region 21. A thickness of the gate wiring 52 is preferably substantially equal to the thickness of the gate electrode 32.

The gate wiring 52 includes a wiring surface 53, a first wiring side wall 54 on the inner edge side, and a second wiring side wall 55 on the outer edge side. The wiring surface 53 extends along the outer peripheral insulating film 51 (first principal surface 3). The wiring surface 53 may extend substantially parallel to the outer peripheral insulating film 51 (first principal surface 3). The first wiring side wall 54 extends in the vertical direction Z on the outer peripheral insulating film 51, and the second wiring side wall 55 extends in the vertical direction Z on the outer peripheral insulating film 51.

The first wiring side wall 54 is connected to the plurality of gate electrodes 32 (the first side wall 34 and the second side wall 35) in a portion extending in the first direction X. That is, the gate wiring 52 has a plurality of portions connected to the plurality of gate electrodes 32 in a T shape. Thus, the gate wiring 52 is fixed at the same potential as the plurality of gate electrodes 32.

The first wiring side wall 54 and the second wiring side wall 55 may extend perpendicularly to the outer peripheral insulating film 51. That is, the gate wiring 52 may be formed in a quadrangular shape (flat rectangular shape) in cross-sectional view. The first wiring side wall 54 and the second wiring side wall 55 may be inclined obliquely toward the wiring surface 53. That is, the gate wiring 52 may be formed in a tapered shape (preferably an isosceles trapezoidal shape) in cross-sectional view.

The semiconductor device 1 includes an insulating interlayer film 70 that covers the first principal surface 3. The interlayer film 70 may be referred to as an “interlayer insulating film,” an “intermediate insulating film,” etc. The interlayer film 70 has an insulating surface 71 extending along the first principal surface 3. The interlayer film 70 collectively covers the active region 8 and the outer peripheral region 9 on the first principal surface 3.

The interlayer film 70 covers the plurality of gate structures 30 in the active region 8. The interlayer film 70 directly covers both the insulating film 31 and the gate electrode 32 with respect to each gate structure 30. That is, the interlayer film 70 has a portion that directly covers the electrode surface 33, the first side wall 34, and the second side wall 35 of the gate electrode 32.

The interlayer film 70 collectively covers the outer body region 21, the terminal region 45, and the plurality of field regions 47 across the outer peripheral insulating film 51 in the outer peripheral region 9. The interlayer film 70 directly covers both the outer peripheral insulating film 51 and the gate wiring 52. That is, the interlayer film 70 has a portion that directly covers the wiring surface 53, the first wiring side wall 54, and the second wiring side wall 55 of the gate wiring 52. In this embodiment, the interlayer film 70 is continuous with the first to fourth side surfaces 5A to 5D. The interlayer film 70 may be formed at intervals inward from the first to fourth side surfaces 5A to 5D and expose the peripheral edge portion (first semiconductor region 6) of the first principal surface 3.

Referring to FIGS. 7 to 9, in this embodiment, the interlayer film 70 has a laminated structure including a first oxide film 72 (first insulating film) and a second oxide film 73 (second insulating film) laminated in this order from the first principal surface 3 side. That is, the interlayer film 70 has the insulating surface 71 formed by the second oxide film 73. The first oxide film 72 has a single layer structure constituted of the silicon oxide film that is not doped with an impurity. The first oxide film 72 may be referred to as an NSG film (non-doped silicate glass film).

The first oxide film 72 collectively covers the active region 8 and the outer peripheral region 9. The first oxide film 72 collectively covers the plurality of gate structures 30 in the active region 8. The first oxide film 72 covers both the insulating film 31 and the gate electrode 32 in a film shape with respect to each gate structure 30.

The first oxide film 72 includes a first covering portion 74, a second covering portion 75, and a third covering portion 76. The first covering portion 74 extends in a film shape in the horizontal direction along the insulating film 31 (first principal surface 3) and has a portion in contact with the first side wall 34 (second side wall 35) of the gate electrode 32. In this embodiment, the first covering portion 74 (first oxide film 72) has a thickness less than the thickness of the gate electrode 32, and covers the insulating film 31 at an interval from a height position of the electrode surface 33 of the gate electrode 32 toward the insulating film 31.

The second covering portion 75 is led out from the first covering portion 74 toward the electrode surface 33 in the lamination direction, and directly covers the first side wall 34 (second side wall 35) in a film shape.

The third covering portion 76 is led out from the second covering portion 75 toward the electrode surface 33, and extends in a film shape in the horizontal direction along the electrode surface 33. The third covering portion 76 directly covers an entire region of the electrode surface 33 between the first side wall 34 and the second side wall 35. The third covering portion 76 preferably forms an arcuate corner portion curved in an arcuate shape together with the second covering portion 75 in a portion covering a corner portion of the gate electrode 32. The arcuate corner portion may have a center of curvature on the gate electrode 32 side.

The first oxide film 72 collectively covers the outer body region 21, the terminal region 45, and the plurality of field regions 47 across the outer peripheral insulating film 51 in the outer peripheral region 9. The first oxide film 72 covers the gate wiring 52 in the outer peripheral region 9.

The second oxide film 73 may have a single layer structure constituted of a silicon oxide film containing phosphorus or a laminated structure including a silicon oxide film containing phosphorus. The silicon oxide film containing phosphorus may contain boron. The silicon oxide film containing phosphorus may be referred to as a PSG film (phosphorus silicon glass film). The silicon oxide film containing both phosphorus and boron may be referred to as a BPSG film (boron phosphorus silicon glass film).

The second oxide film 73 may have a single layer structure constituted of a PSG film or a BPSG film laminated on the first oxide film 72. The second oxide film 73 may have a laminated structure including a PSG film laminated on the first oxide film 72 and a BPSG film laminated on the PSG film. The second oxide film 73 may have a laminated structure including a BPSG film laminated on the first oxide film 72 and a PSG film laminated on the BPSG film. In this embodiment, the second oxide film 73 has a single layer structure constituted of a PSG film as an example.

The second oxide film 73 covers the first oxide film 72 in a film shape, and collectively covers the active region 8 and the outer peripheral region 9 across the first oxide film 72. The second oxide film 73 collectively covers the plurality of gate structures 30 across the first oxide film 72 in the active region 8. Specifically, the second oxide film 73 covers both the insulating film 31 and the gate electrode 32 in a film shape across the first oxide film 72.

The second oxide film 73 includes a first upper covering portion 80 and a second upper covering portion 81. The first upper covering portion 80 covers the first covering portion 74 of the first oxide film 72. The first upper covering portion 80 covers the insulating film 31 across the first covering portion 74 in a portion positioned on the first covering portion 74.

The first upper covering portion 80 extends in a film shape in the lamination direction along the second covering portion 75 from above the first covering portion 74, and covers the first side wall 34 (second side wall 35) of the gate structure 30 across the second covering portion 75.

The second upper covering portion 81 covers the third covering portion 76 of the first oxide film 72. The second upper covering portion 81 extends in a film shape in the horizontal direction from the first upper covering portion 80 along the third covering portion 76, and covers the electrode surface 33 of the gate structure 30 across the third covering portion 76. The second upper covering portion 81 covers the entire region of the electrode surface 33 across the third covering portion 76 between the first side wall 34 and the second side wall 35. The second upper covering portion 81 preferably forms an arcuate corner portion curved in an arcuate shape together with the first upper covering portion 80 in a portion covering the corner portion of the gate wiring 52. The arcuate corner portion may have a center of curvature on the gate wiring 52 side.

The second oxide film 73 collectively covers the outer body region 21, the terminal region 45, and the plurality of field regions 47 across the outer peripheral insulating film 51 and the first oxide film 72 in the outer peripheral region 9. The second oxide film 73 covers the gate wiring 52 across the first oxide film 72 in the outer peripheral region 9.

The semiconductor device 1 includes a plurality of source openings 90 formed in the interlayer film 70 in the active region 8. The plurality of source openings 90 are formed in regions at sides of the plurality of gate electrodes 32 at intervals from the plurality of gate electrodes 32, respectively, and expose the first principal surface 3 (chip 2). Specifically, the plurality of source openings 90 are formed in regions between the plurality of gate electrodes 32, respectively, and penetrate through the insulating film 31 and the interlayer film 70.

The plurality of source openings 90 have wall surfaces penetrating through both the first oxide film 72 and the second oxide film 73 and demarcated by both the first oxide film 72 and the second oxide film 73. The plurality of source openings 90 have opening ends demarcated by arcuate corner portions of the interlayer film 70. The plurality of source openings 90 respectively expose the corresponding plurality of source regions 23 (the first source region 24A and the second source region 24B) and the contact region 25.

In this embodiment, the plurality of source openings 90 are formed at intervals in the first direction X, and are each formed in a band shape extending in the second direction Y. That is, the plurality of source openings 90 are formed in a stripe shape extending in the second direction Y. The plurality of source openings 90 are formed at intervals in the second direction Y from the gate wiring 52. That is, the plurality of source openings 90 are formed in a region surrounded by the plurality of gate electrodes 32 and the gate wiring 52.

The plurality of source openings 90 may be formed in a region between two gate structures 30 adjacent to each other in the first direction X. In this case, the plurality of source openings 90 may be formed at intervals in a line in the second direction Y. Furthermore, in this case, each source opening 90 may be formed in a quadrangular shape (square shape), a rectangular shape extending in the first direction X, a rectangular shape extending in the second direction Y, a hexagonal shape, a circular shape, etc., in plan view.

The source opening 90 may have a width W of 0.2 μm or more and 3 μm or less. The width W of the source opening 90 is preferably 0.3 μm or more and 1 μm or less. The source opening 90 may have a depth D of 0.2 μm or more and 2 μm or less. The depth D of the source opening 90 is preferably 0.5 μm or more and 1 μm or less.

The source opening 90 preferably has an aspect ratio D/W of 0.3 or more and 3 or less. The aspect ratio D/W is defined by the ratio of the depth D of the source opening 90 with respect to the width W of the source opening 90. The aspect ratio D/W is preferably 0.5 or more and 2 or less. The aspect ratio D/W is particularly preferably more than 1. According to this configuration, the plurality of gate structures 30 are arranged at a narrow pitch.

The semiconductor device 1 includes a plurality of source recesses 91 formed in portions of the first principal surface 3 exposed from the plurality of source openings 90, respectively. The semiconductor device 1 does not necessarily have to include the source recess 91. Therefore, a configuration without the source recess 91 may be adopted.

Each of the plurality of source recesses 91 has a planar shape matching the planar shape of the corresponding source opening 90, and is recessed from the first principal surface 3 toward the second principal surface 4. Each of the plurality of source recesses 91 is formed at an interval from the bottom portion of the corresponding body region 20 toward the first principal surface 3, and exposes the corresponding plurality of source regions 23 and the contact region 25. Specifically, the plurality of source recesses 91 are formed at an interval from bottom portions of the corresponding plurality of source regions 23 (contact region 25) toward the first principal surface 3.

The semiconductor device 1 includes at least one (in this embodiment, a plurality of) outer opening 92 formed in the interlayer film 70 in the outer peripheral region 9. The plurality of outer openings 92 are formed in a portion of the interlayer film 70 covering the terminal region 45. The plurality of outer openings 92 penetrate through the interlayer film 70 and expose the terminal region 45. In this embodiment, the plurality of outer openings 92 are formed in a portion of the interlayer film 70 covering the overlap region 46 of the terminal region 45 and expose the overlap region 46.

The plurality of outer openings 92 may expose the outer body region 21 instead of or in addition to the terminal region 45 (overlap region 46). The plurality of outer openings 92 have wall surfaces penetrating through both the first oxide film 72 and the second oxide film 73 and demarcated by both the first oxide film 72 and the second oxide film 73. The plurality of outer openings 92 have opening ends demarcated by the arcuate corner portions of the interlayer film 70.

The plurality of outer openings 92 are formed at intervals along the terminal region 45 (overlap region 46) (see FIGS. 4 and 5). The plurality of outer openings 92 may be formed in a quadrangular shape (square shape), a rectangular shape, a hexagonal shape, a circular shape, etc., in plan view. The plurality of outer openings 92 may be formed in a band shape extending along the terminal region 45 (overlap region 46) in plan view. Similarly to the source opening 90, the outer opening 92 may have an aspect ratio D/W (preferably more than 1).

The semiconductor device 1 may have a single outer opening 92. The single outer opening 92 may be formed in a band shape extending along the terminal region 45 (overlap region 46). The single outer opening 92 may have a portion extending in a band shape in the first direction X and a portion extending in a band shape in the second direction Y in plan view.

The single outer opening 92 may be formed in a polygonal annular shape (a quadrangular annular shape in this embodiment) with or without ends having four sides parallel to the peripheral edges of the first principal surface 3. The single outer opening 92 may have an edge portion connecting the portion extending in the first direction X and the portion extending in the second direction Y in conformance to the terminal region 45 (overlap region 46) in plan view in an arcuate shape (preferably a quadrant arcuate shape) (see FIG. 4).

The semiconductor device 1 includes a plurality of outer recesses 93 formed in portions of the first principal surface 3 exposed from the plurality of outer openings 92, respectively. The semiconductor device 1 does not necessarily have to include the outer recess 93. Therefore, a configuration without the outer recess 93 may be adopted.

Each of the plurality of outer recesses 93 has a planar shape matching the planar shape of the corresponding outer opening 92, and is recessed from the first principal surface 3 toward the second principal surface 4. The plurality of outer recesses 93 are formed at intervals from a bottom portion of the terminal region 45 (overlap region 46) toward the first principal surface 3 and expose the terminal region 45 (overlap region 46), respectively. When the single outer opening 92 is formed, a single outer recess 93 matching the planar shape of the single outer opening 92 is formed.

The semiconductor device 1 includes at least one (in this embodiment, a plurality of) gate opening 94 formed in the interlayer film 70 in the outer peripheral region 9. The plurality of gate openings 94 are formed in a portion of the interlayer film 70 covering the gate wiring 52. The plurality of gate openings 94 penetrate through the interlayer film 70 and expose the wiring surface 53 of the gate wiring 52.

The plurality of gate openings 94 have wall surfaces penetrating through both the first oxide film 72 and the second oxide film 73 and demarcated by both the first oxide film 72 and the second oxide film 73. The plurality of gate openings 94 have opening ends demarcated by the arcuate corner portions of the interlayer film 70.

The plurality of gate openings 94 are formed at intervals along the gate wiring 52 (see FIGS. 4 and 5). The plurality of gate openings 94 may be formed in a quadrangular shape (square shape), a rectangular shape, a hexagonal shape, a circular shape, etc., in plan view. The plurality of gate openings 94 may be formed in a band shape extending along the gate wiring 52 in plan view. Similarly to the source opening 90, the gate opening 94 may have an aspect ratio D/W (preferably, more than 1).

The semiconductor device 1 may have a single gate opening 94. The single gate opening 94 may be formed in a band shape extending along the gate wiring 52. The single gate opening 94 may have a portion extending in a band shape in the first direction X and a portion extending in a band shape in the second direction Y in plan view.

The single gate opening 94 may be formed in a polygonal annular shape (a quadrangular annular shape in this embodiment) with or without ends having four sides parallel to the peripheral edges of the first principal surface 3. The single gate opening 94 may have an edge portion connecting the portion extending in the first direction X and the portion extending in the second direction Y in conformance to the gate wiring 52 in plan view in an arcuate shape (preferably a quadrant arcuate shape) (see FIG. 4).

Referring to FIG. 1, etc., the semiconductor device 1 includes a source pad electrode 95 disposed on the interlayer film 70. The source pad electrode 95 is a terminal electrode to which a source potential is externally applied. The source pad electrode 95 may be referred to as a “first pad electrode,” a “first principal surface electrode,” a “first terminal electrode,” etc.

The source pad electrode 95 is disposed on a portion of the interlayer film 70 covering the active region 8. The source pad electrode 95 covers the plurality of gate electrodes 32 across the interlayer film 70, and is electrically separated from the plurality of gate electrodes 32 by the interlayer film 70. The source pad electrode 95 is electrically connected to the plurality of body regions 20, the outer body region 21, the plurality of source regions 23 (the first source region 24A and the second source region 24B), the contact region 25, etc., through the plurality of source openings 90.

In this embodiment, the source pad electrode 95 includes a first pad portion 96, a second pad portion 97, and a third pad portion 98. The first pad portion 96 has a relatively large plane area, and forms a main body of the source pad electrode 95. In this embodiment, the first pad portion 96 is formed in a polygonal shape (a quadrangular shape in this embodiment) having four sides parallel to the peripheral edges of the chip 2 in plan view, and is shifted further to the fourth side surface 5D side with respect to a central portion of the active region 8. The first pad portion 96 covers the plurality of gate electrodes 32 across the interlayer film 70, and is electrically connected to the plurality of body regions 20, etc., through the plurality of source openings 90.

The second pad portion 97 has a plane area less than the plane area of the first pad portion 96, and is led out in a band shape (quadrangular shape) from one end portion (end portion on the first side surface 5A side) of the first pad portion 96 in the second direction Y toward the third side surface 5C. The second pad portion 97 covers the plurality of gate electrodes 32 across the interlayer film 70, and is electrically connected to the plurality of body regions 20, etc., through the plurality of source openings 90.

The third pad portion 98 has a plane area less than the plane area of the first pad portion 96, is led out in a band shape (quadrangular shape) from the other end portion (end portion on the second side surface 5B side) of the first pad portion 96 in the second direction Y toward the third side surface 5C, and faces the second pad portion 97 in the second direction Y. The third pad portion 98 covers the plurality of gate electrodes 32 across the interlayer film 70, and is electrically connected to the plurality of body regions 20, etc., through the plurality of source openings 90.

The plane area of the third pad portion 98 may be substantially equal to the plane area of the second pad portion 97. As a matter of course, the plane area of the third pad portion 98 may be larger than the plane area of the second pad portion 97, or may be less than the plane area of the second pad portion 97. Either or both of the second pad portion 97 and the third pad portion 98 may be used as a terminal portion for current monitoring.

The source pad electrode 95 does not necessarily have to include both the second pad portion 97 and the third pad portion 98 at the same time. The source pad electrode 95 may include only one of the second pad portion 97 and the third pad portion 98. As a matter of course, the source pad electrode 95 may be constituted of only the first pad portion 96, and does not have to include the second pad portion 97 and the third pad portion 98.

Referring to FIGS. 7 to 9, the source pad electrode 95 includes a first base electrode film 100 and a first principal electrode film 102. The first base electrode film 100 may be referred to as a “source base electrode film,” and the first principal electrode film 102 may be referred to as a “source principal electrode film.”

The first base electrode film 100 forms a lower layer portion of the source pad electrode 95 (the first pad portion 96, the second pad portion 97, and the third pad portion 98), and covers the interlayer film 70 in the active region 8. The first base electrode film 100 collectively covers a region of the interlayer film 70 where the plurality of source openings 90 are formed in a film shape. That is, the first base electrode film 100 enters into the plurality of source openings 90 from above the insulating surface 71.

The first base electrode film 100 has a portion covering the insulating surface 71 of the interlayer film 70 in a film shape and a portion covering the wall surfaces of the plurality of source openings 90 in a film shape. The first base electrode film 100 demarcates recesses in the plurality of source openings 90, respectively. The first base electrode film 100 may have a portion partially covering the gate wiring 52 across the interlayer film 70. The first base electrode film 100 may be formed at an interval inward from the gate wiring 52 in plan view.

In this embodiment, the first base electrode film 100 has a laminated structure including a first electrode film 103 laminated on the interlayer film 70 and a second electrode film 104 laminated on the first electrode film 103. In this embodiment, the first electrode film 103 includes a Ti film, and the second electrode film 104 includes a TiN film.

The first base electrode film 100 does not necessarily have to have a laminated structure, and may have a single layer structure constituted of one of the first electrode film 103 (Ti film) and the second electrode film 104 (TiN film). A thickness of the first electrode film 103 may be 10 nm or more and 100 nm or less. A thickness of the second electrode film 104 may be 50 nm or more and 200 nm or less.

The first electrode film 103 collectively covers the region of the interlayer film 70 where the plurality of source openings 90 are formed in a film shape, and enters into the plurality of source openings 90 from above the insulating surface 71. The first electrode film 103 has a portion covering the insulating surface 71 of the interlayer film 70 in a film shape and a portion covering the wall surfaces of the plurality of source openings 90 in a film shape. The first electrode film 103 directly covers the insulating surface 71.

That is, the first electrode film 103 directly covers the second oxide film 73 on the insulating surface 71. The first oxide film 72 faces the plurality of gate electrodes 32 across the interlayer film 70 in a portion covering the insulating surface 71.

The first electrode film 103 covers the arcuate corner portion of the interlayer film 70 (second oxide film 73) in a film shape in conformance to such arcuate corner portion, and enters into the source opening 90. That is, the first electrode film 103 has a portion extending in an arcuate shape at the arcuate corner portion. Thus, the film formability of the first electrode film 103 with respect to the interlayer film 70 (the wall surface of the source opening 90) is improved.

The first electrode film 103 extends along the wall surface of the source opening 90 and covers the insulating film 31, the first oxide film 72, and the second oxide film 73. The first electrode film 103 faces the first side wall 34 (second side wall 35) of the gate electrode 32 across the interlayer film 70.

The first electrode film 103 covers the first principal surface 3 in a film shape at a bottom portion of each source opening 90, and is electrically connected to the first principal surface 3. Specifically, the first electrode film 103 has a portion covering the bottom portion of each source opening 90 in a film shape, and is electrically connected to the plurality of source regions 23 (the first source region 24A and the second source region 24B) and the contact region 25.

The second electrode film 104 collectively covers the region of the interlayer film 70 where the plurality of source openings 90 are formed in a film shape on the first electrode film 103. The second electrode film 104 has a portion covering the insulating surface 71 of the interlayer film 70 in a film shape across the first electrode film 103, and a portion covering the wall surfaces of the plurality of source openings 90 in a film shape across the first electrode film 103.

The second electrode film 104 faces the plurality of gate electrodes 32 across the first electrode film 103 and the interlayer film 70 in a portion covering the insulating surface 71.

The second electrode film 104 covers the arcuate corner portion of the interlayer film 70 (second oxide film 73) in a film shape in conformance to the first electrode film 103, and enters into the source opening 90. That is, the second electrode film 104 has a portion extending in an arcuate shape at the arcuate corner portion of the interlayer film 70. Thus, the film formability of the second electrode film 104 with respect to the interlayer film 70 (the wall surface of the source opening 90) is improved.

The second electrode film 104 extends along the wall surface of the source opening 90, and covers the insulating film 31, the first oxide film 72, and the second oxide film 73 across the first electrode film 103. The second electrode film 104 faces the first side wall 34 (second side wall 35) of the gate electrode 32 across the first electrode film 103 and the interlayer film 70.

The second electrode film 104 has a portion covering the bottom portion of each source opening 90 in a film shape across the first electrode film 103, and is electrically connected to the plurality of source regions 23 (the first source region 24A and the second source region 24B) and the contact region 25.

The first principal electrode film 102 forms an upper layer portion of the source pad electrode 95 (the first pad portion 96, the second pad portion 97, and the third pad portion 98) and covers the first base electrode film 100 in a film shape. The first principal electrode film 102 contains a conductive material different from the conductive material of the first base electrode film 100.

The first principal electrode film 102 may include at least one among an Al film, an Al alloy film, a Cu film, and a Cu alloy film. The Al alloy film may include at least one among an AlSi alloy film, an AlCu alloy film, and an AlSiCu alloy film. The first principal electrode film 102 has a thickness larger than the thickness (total thickness) of the first base electrode film 100.

The thickness of the first principal electrode film 102 may be 0.5 μm or more and 5 μm or less. The thickness of the first principal electrode film 102 may have a value belonging to at least one range among 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less.

The first principal electrode film 102 is mechanically and electrically connected to the first base electrode film 100 in a portion covering the insulating surface 71. As a result, the first principal electrode film 102 faces the plurality of gate electrodes 32 across the first base electrode film 100 and the interlayer film 70.

The semiconductor device 1 includes a source finger electrode 110 led out from the source pad electrode 95 onto the outer peripheral region 9. The source finger electrode 110 transmits the source potential applied to the source pad electrode 95 to the outer peripheral region 9. In this embodiment, the source finger electrode 110 is routed from a portion of the source pad electrode 95 (first pad portion 96) on the fourth side surface 5D side onto a portion of the interlayer film 70 covering the outer peripheral region 9.

The source finger electrode 110 is led out above the terminal region 45, and is electrically connected to the terminal region 45 through the plurality of outer openings 92. Specifically, the source finger electrode 110 is electrically connected to the overlap region 46 of the terminal region 45 through the plurality of outer openings 92.

The source finger electrode 110 extends in a band shape along the terminal region 45 (overlap region 46). The source finger electrode 110 has a portion extending in a band shape in the first direction X and a portion extending in a band shape in the second direction Y in plan view. In this embodiment, the source finger electrode 110 is formed in a polygonal annular shape (in this embodiment, a quadrangular annular shape) having four sides parallel to the peripheral edges of the first principal surface 3, and surrounds the source pad electrode 95. The source finger electrode 110 may have an edge portion connecting the portion extending in the first direction X and the portion extending in the second direction Y in plan view in an arcuate shape (preferably a quadrant arcuate shape) (see FIG. 4).

Similarly to the source pad electrode 95, the source finger electrode 110 includes the first base electrode film 100 and the first principal electrode film 102. The first base electrode film 100 forms a lower layer portion of the source finger electrode 110, and covers the interlayer film 70 in the outer peripheral region 9.

The first base electrode film 100 collectively covers a region of the interlayer film 70 where the plurality of outer openings 92 are formed in a film shape. That is, the first base electrode film 100 enters into the plurality of outer openings 92 from above the insulating surface 71. The first base electrode film 100 has a portion covering the insulating surface 71 of the interlayer film 70 in a film shape and a portion covering the wall surfaces of the plurality of outer openings 92 in a film shape. The first base electrode film 100 demarcates recesses in the plurality of outer openings 92, respectively. Similarly to the source pad electrode 95, the first base electrode film 100 has a laminated structure including the first electrode film 103 and the second electrode film 104.

The first principal electrode film 102 forms an upper layer portion of the source finger electrode 110 and covers the first base electrode film 100 in a film shape. The first principal electrode film 102 is mechanically and electrically connected to the first base electrode film 100 in a portion covering the insulating surface 71. That is, the first principal electrode film 102 is electrically connected to the terminal region 45 (overlap region 46) through the first base electrode film 100.

The semiconductor device 1 includes a gate finger electrode 115 selectively routed on the interlayer film 70. The gate finger electrode 115 transmits a gate potential to the gate wiring 52. The gate finger electrode 115 is routed on a portion of the interlayer film 70 covering the gate wiring 52 (that is, on the outer peripheral region 9), and is electrically connected to the gate wiring 52 through the plurality of gate openings 94.

The gate finger electrode 115 is disposed in a region between the source pad electrode 95 and the source finger electrode 110 at an interval from the source pad electrode 95 and the source finger electrode 110. The gate finger electrode 115 is disposed on the gate wiring 52 and extends in a band shape along the gate wiring 52. The gate finger electrode 115 has a portion extending in a band shape in the first direction X and a portion extending in a band shape in the second direction Y in plan view.

In this embodiment, the gate finger electrode 115 is formed in a band shape with ends having four sides parallel to the peripheral edges of the first principal surface 3, and surrounds the source pad electrode 95. The gate finger electrode 115 may have an edge portion connecting the portion extending in the first direction X and the portion extending in the second direction Y in plan view in an arcuate shape (preferably a quadrant arcuate shape) (see FIG. 4). The gate finger electrode 115 has a pair of open ends that allow the source finger electrode 110 to pass therethrough on the fourth side surface 5D side.

Referring to FIG. 10, the gate finger electrode 115 includes a second base electrode film 120 and a second principal electrode film 122. The second base electrode film 120 may be referred to as a “gate base electrode film,” and the second principal electrode film 122 may be referred to as a “gate principal electrode film.”

The second base electrode film 120 forms a lower layer portion of the gate finger electrode 115 and covers the interlayer film 70 in the outer peripheral region 9. The second base electrode film 120 collectively covers a region of the interlayer film 70 where the plurality of gate openings 94 are formed in a film shape. That is, the second base electrode film 120 enters into the plurality of gate openings 94 from above the insulating surface 71. The second base electrode film 120 has a portion covering the insulating surface 71 of the interlayer film 70 in a film shape and a portion covering the wall surfaces of the plurality of gate openings 94 in a film shape. The second base electrode film 120 demarcates a plurality of recesses in the plurality of gate openings 94, respectively.

The second base electrode film 120 has a similar laminated structure as the first electrode film 103 and the second electrode film 104 of the first base electrode film 100. Since the laminated structure of the second base electrode film 120 is similar to the laminated structure of the first electrode film 103 and the second electrode film 104 of the first base electrode film 100, the description thereof is omitted.

The second principal electrode film 122 forms an upper layer portion of the gate finger electrode 115 and covers the second base electrode film 120 in a film shape. The second principal electrode film 122 contains a conductive material different from the conductive material of the second base electrode film 120.

The second principal electrode film 122 may include at least one among an Al film, an Al alloy film, a Cu film, and a Cu alloy film. The Al alloy film may include at least one among an AlSi alloy film, an AlCu alloy film, and an AlSiCu alloy film. The second principal electrode film 122 preferably contains the same type of conductive material as the conductive material of the first principal electrode film 102. The second principal electrode film 122 may have a thickness substantially equal to the thickness of the first principal electrode film 102.

The second principal electrode film 122 is mechanically and electrically connected to the second base electrode film 120 in a portion covering the insulating surface 71.

The semiconductor device 1 includes a gate pad electrode 130 disposed on the interlayer film 70. The gate pad electrode 130 is a terminal electrode to which a gate potential is externally applied. The gate pad electrode 130 may be referred to as a “second pad electrode,” a “second principal surface electrode,” a “second terminal electrode,” etc. The gate pad electrode 130 is disposed in a region between the source pad electrode 95 and the source finger electrode 110 at an interval from the source pad electrode 95 and the source finger electrode 110.

In this embodiment, the gate pad electrode 130 is disposed in a region on the third side surface 5C side with respect to the first pad portion 96, and is sandwiched between the second pad portion 97 and the third pad portion 98. That is, the gate pad electrode 130 faces the first pad portion 96 in the first direction X, and faces the second pad portion 97 and the third pad portion 98 in the second direction Y.

The gate pad electrode 130 is formed in a polygonal shape (a quadrangular shape in this embodiment) having four sides parallel to the peripheral edges of the chip 2 in plan view. The gate pad electrode 130 has a plane area less than a plane area of the source pad electrode 95 (first pad portion 96). The gate pad electrode 130 may have a plane area less than the plane area of the second pad portion 97 (third pad portion 98).

The gate pad electrode 130 is disposed on a portion covering the active region 8 and the outer peripheral region 9, and is connected to the gate finger electrode 115. The gate pad electrode 130 may cover the plurality of gate electrodes 32 across the interlayer film 70, or may cover the gate wiring 52 across the interlayer film 70.

Similarly to the gate finger electrode 115, the gate pad electrode 130 includes the second base electrode film 120 and the second principal electrode film 122. The second base electrode film 120 forms a lower layer portion of the gate pad electrode 130 and covers the interlayer film 70 in a film shape. The second principal electrode film 122 forms an upper layer portion of the gate pad electrode 130 and covers the second base electrode film 120 in a film shape.

The gate potential applied to the gate pad electrode 130 is applied to the gate wiring 52 through the gate finger electrode 115. The gate potential is transmitted to the plurality of gate electrodes 32 through a wiring path (current path) along the gate wiring 52. As a result, the plurality of gate electrodes 32 are turned on, and on/off of the plurality of channel regions 26 and 27 is controlled.

The semiconductor device 1 includes a drain pad electrode 140 covering the second principal surface 4. The drain pad electrode 140 is a terminal electrode to which a drain potential is externally applied. The drain pad electrode 140 may be referred to as a “third pad electrode,” a “third principal surface electrode,” a “third terminal electrode,” etc. The drain pad electrode 140 is electrically connected to the second semiconductor region 7. The drain pad electrode 140 may cover an entire region of the second principal surface 4 such as to be continuous with the peripheral edges (the first to fourth side surfaces 5A to 5D) of the second principal surface 4. The drain pad electrode 140 may partially cover the second principal surface 4 such as to expose a peripheral edge portion of the second principal surface 4.

A breakdown voltage that can be applied between the source pad electrode 95 and the drain pad electrode 140 (between the first principal surface 3 and the second principal surface 4) may be 500 V or more and 3000 V or less. The breakdown voltage may have a value belonging to at least one range among 500 V or more and 1000 V or less, 1000 V or more and 1500 V or less, 1500 V or more and 2000 V or less, 2000 V or more and 2500 V or less, and 2500 V or more and 3000 V or less.

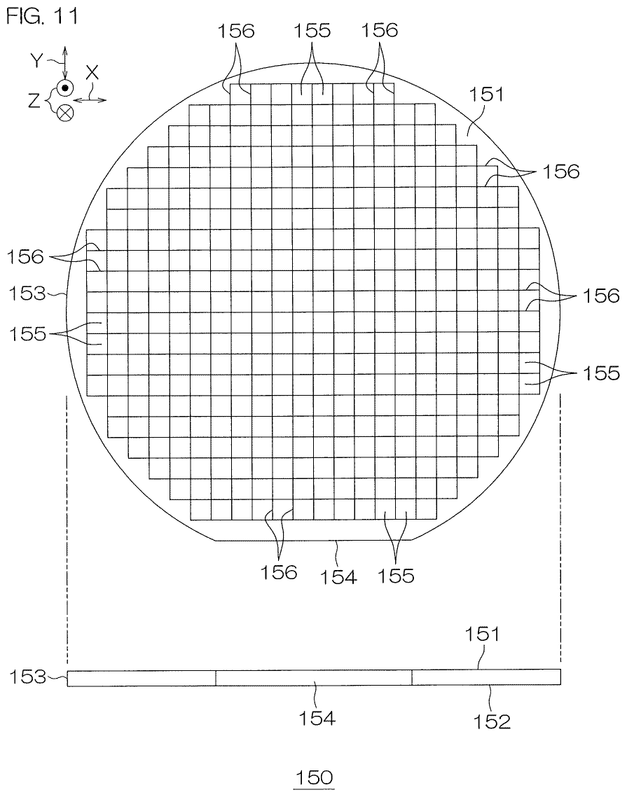

FIG. 11 is a schematic view illustrating a wafer 150 used for manufacturing the semiconductor device 1. Referring to FIG. 11, the wafer 150 is a base material of the chip 2 and includes an SiC monocrystal. The wafer 150 is formed in a flat disc shape. As a matter of course, the wafer 150 may be formed in a flat rectangular parallelepiped shape. The wafer 150 has a first wafer principal surface 151 on one side, a second wafer principal surface 152 on the other side, and a wafer side surface 153 connecting the first wafer principal surface 151 and the second wafer principal surface 152.

The first wafer principal surface 151 corresponds to the first principal surface 3 of the chip 2, and the second wafer principal surface 152 corresponds to the second principal surface 4 of the chip 2. The first wafer principal surface 151 and the second wafer principal surface 152 are formed by the c-plane of the SiC monocrystal. The first wafer principal surface 151 is formed by a silicon plane of the SiC monocrystal, and the second wafer principal surface 152 is formed by a carbon plane of the SiC monocrystal. The wafer 150 (the first wafer principal surface 151 and the second wafer principal surface 152) has the above-described off direction and off angle.

The wafer 150 has a mark 154 indicating a crystal orientation of the SiC monocrystal on the wafer side surface 153. The mark 154 may include either or both of an orientation flat and an orientation notch. The orientation flat is constituted of a notched portion that is notched rectilinearly in plan view. The orientation notch is constituted of a notched portion that is notched in a recessed shape (for example, a tapered shape) toward a central portion of the first wafer principal surface 151 in plan view.

The mark 154 may include either or both of a first orientation flat extending in the m-axis direction and a second orientation flat extending in the a-axis direction. The mark 154 may include either or both of an orientation notch recessed in the m-axis direction and an orientation notch recessed in the a-axis direction.

The wafer 150 includes the first semiconductor region 6 in a region (surface layer portion) on the first wafer principal surface 151 side. The first semiconductor region 6 is formed in a layer shape extending along the first wafer principal surface 151. In this embodiment, the first semiconductor region 6 consists of an epitaxial layer (specifically, an SiC epitaxial layer).

The wafer 150 includes the second semiconductor region 7 in a region (surface layer portion) on the second wafer principal surface 152 side. The second semiconductor region 7 is formed in a layer shape extending along the second principal surface 4 and is electrically connected to the first semiconductor region 6. In this embodiment, the second semiconductor region 7 is constituted of a wafer main body (specifically, an SiC wafer). That is, in this embodiment, the wafer 150 is constituted of an epitaxial wafer (so-called epi-wafer) having a laminated structure including the wafer main body and the epitaxial layer.

For example, a plurality of device regions 155 and a plurality of intended cutting lines 156 are set in the wafer 150 by an alignment mark, etc. Each device region 155 is a region corresponding to the semiconductor device 1. The plurality of device regions 155 are each set in a quadrangular shape in plan view.

In this embodiment, the plurality of device regions 155 are set in a matrix along the first direction X and the second direction Y in plan view. The plurality of device regions 155 are each set at an interval inward from the peripheral edge of the first wafer principal surface 151 in plan view. The plurality of intended cutting lines 156 are set in a lattice extending along the first direction X and the second direction Y such as to demarcate the plurality of device regions 155.

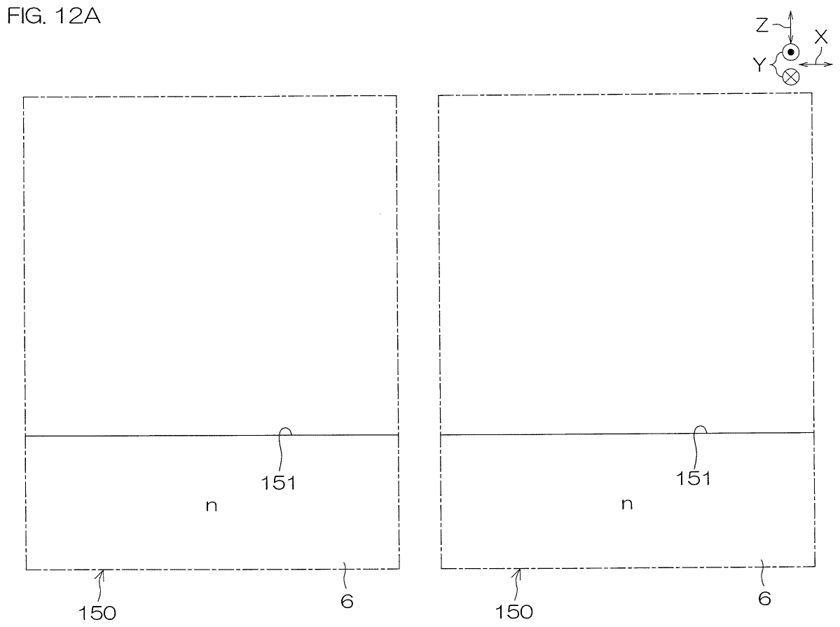

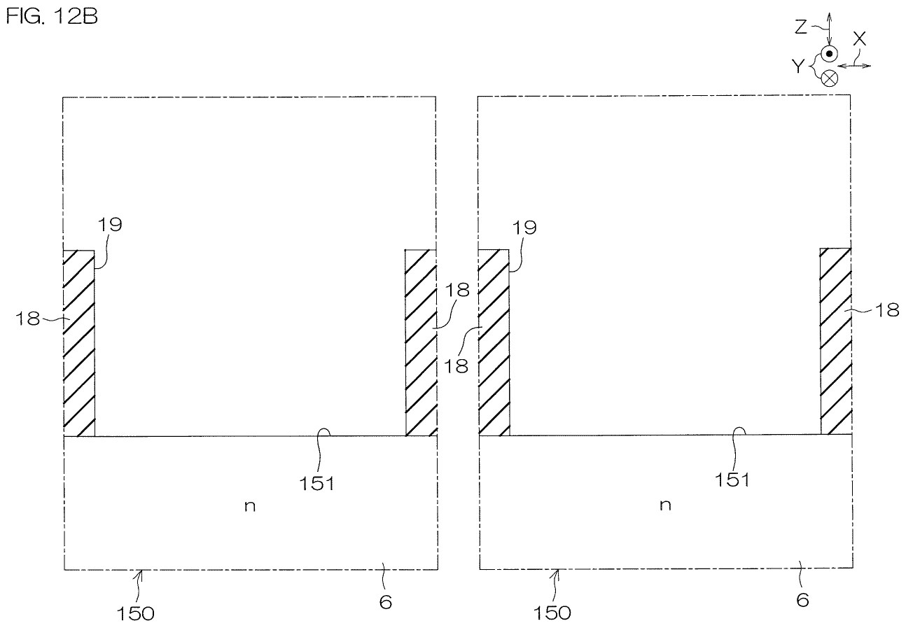

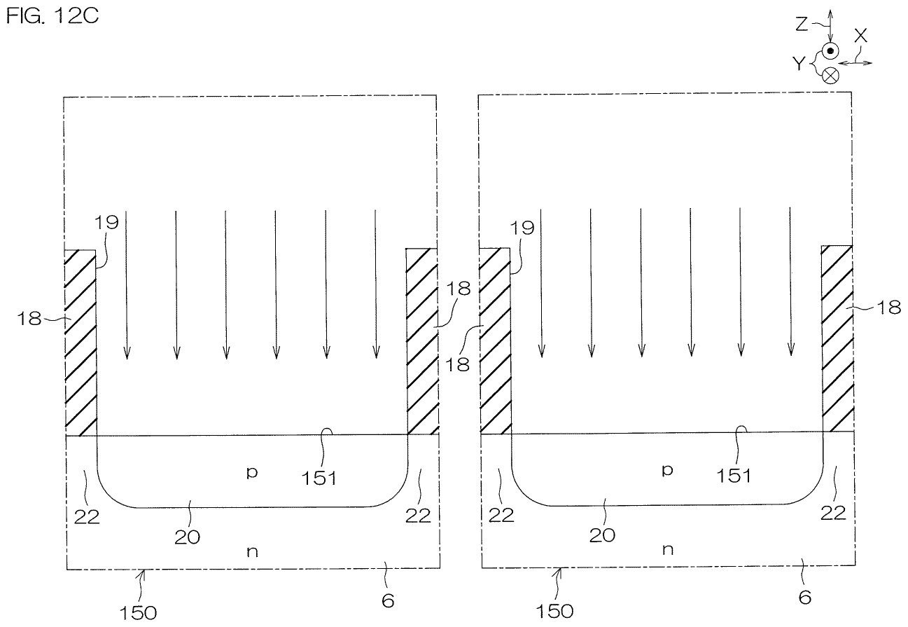

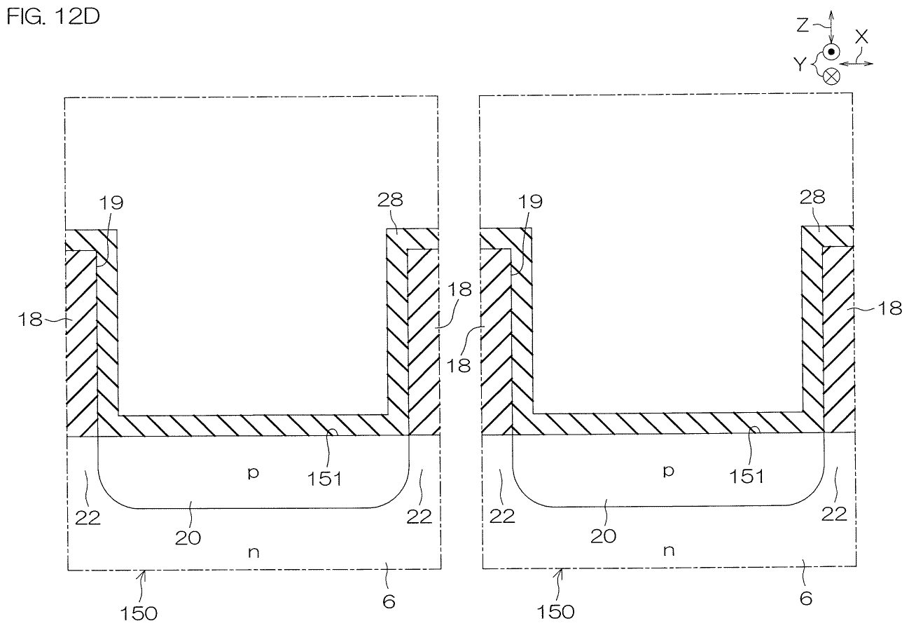

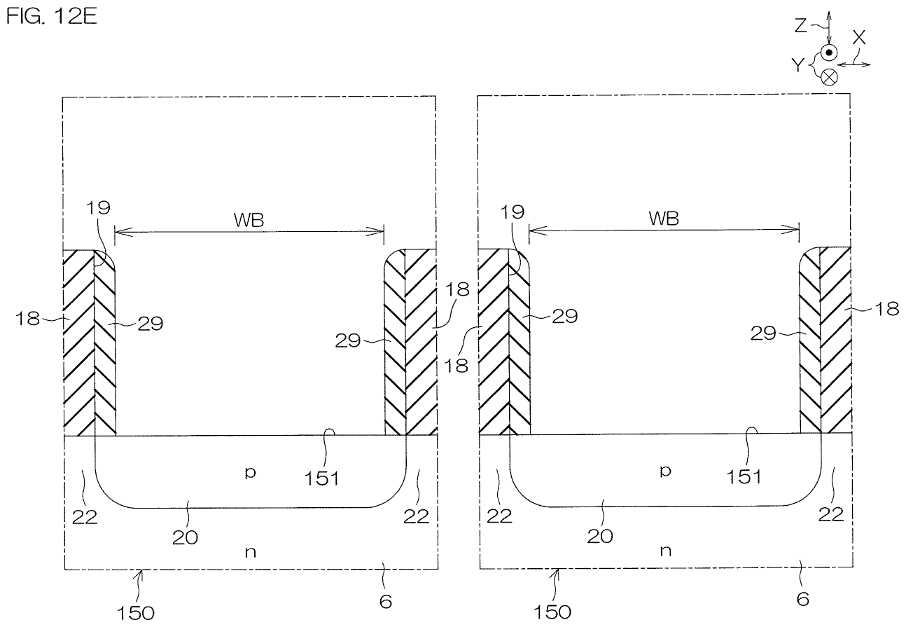

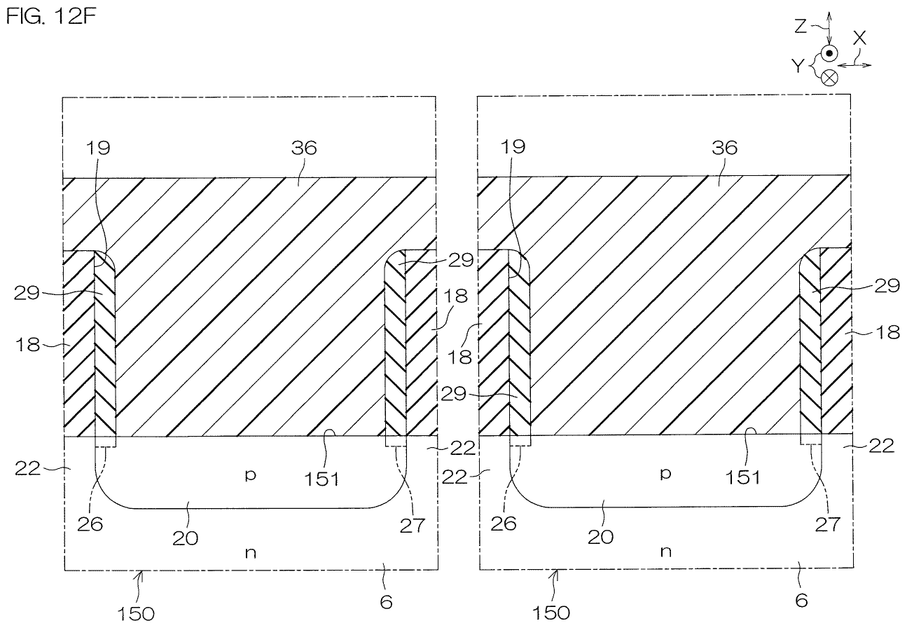

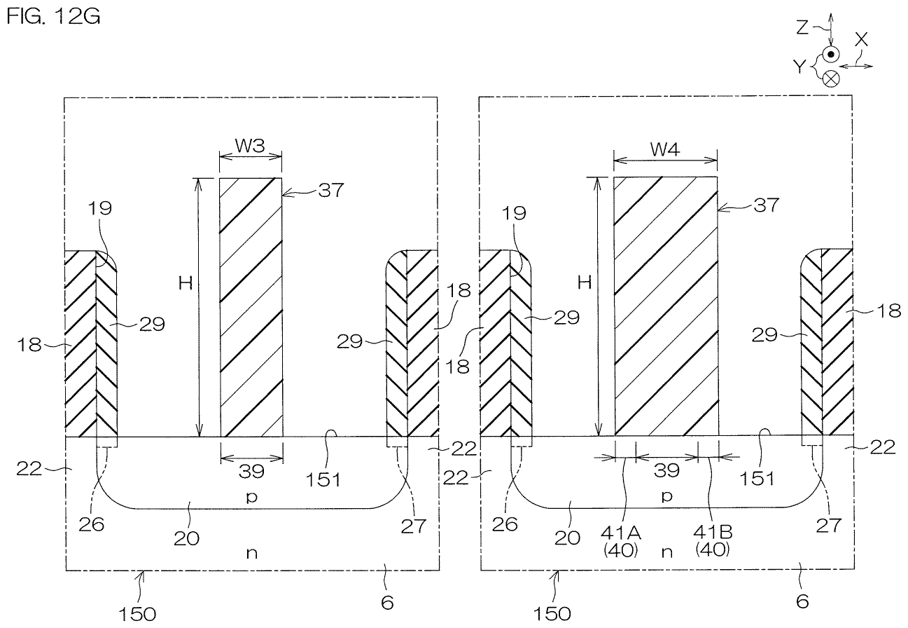

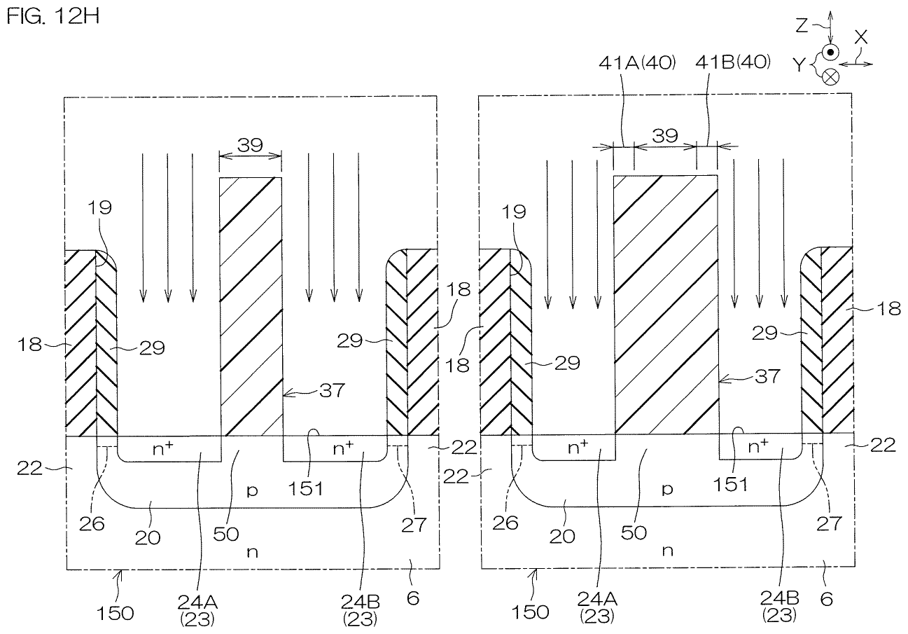

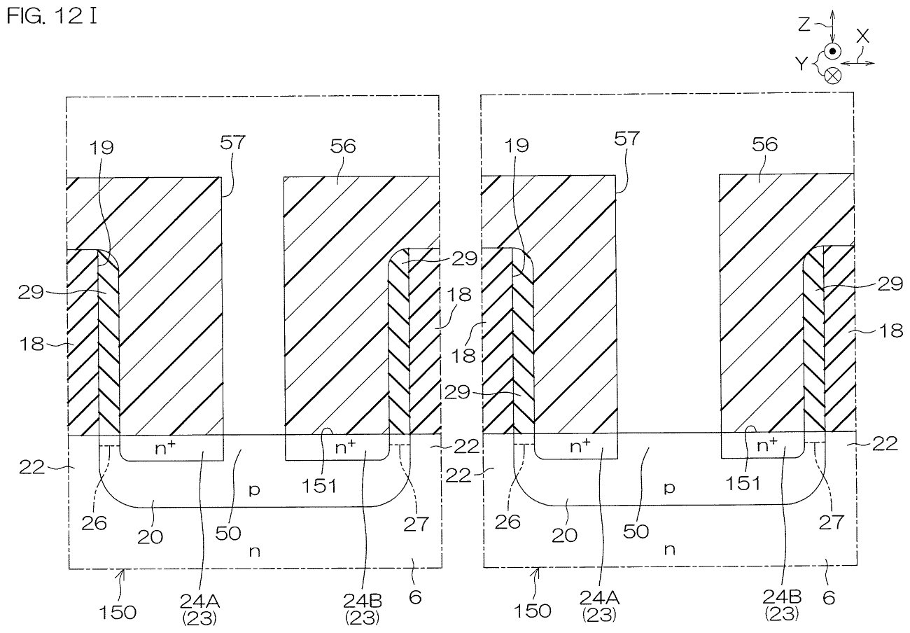

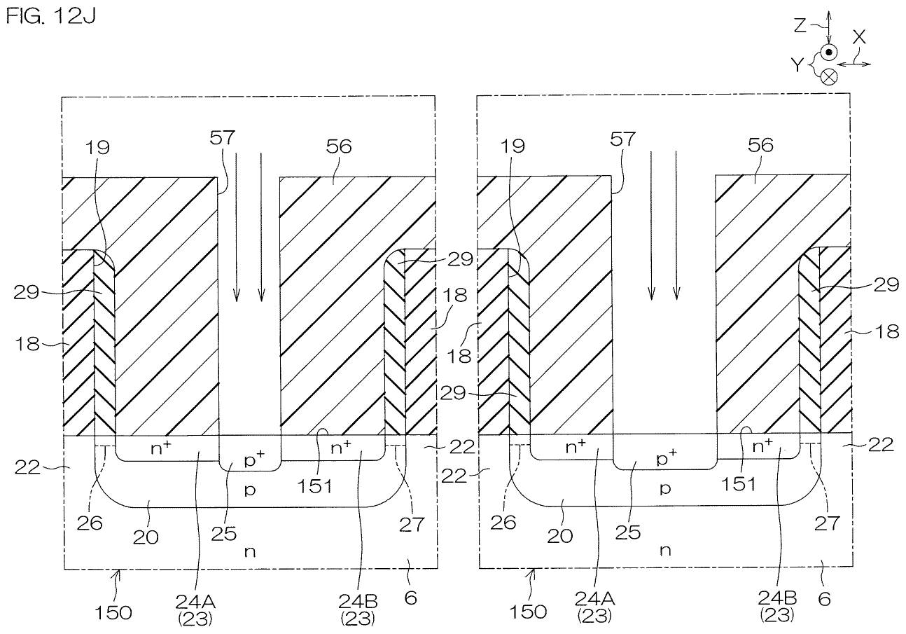

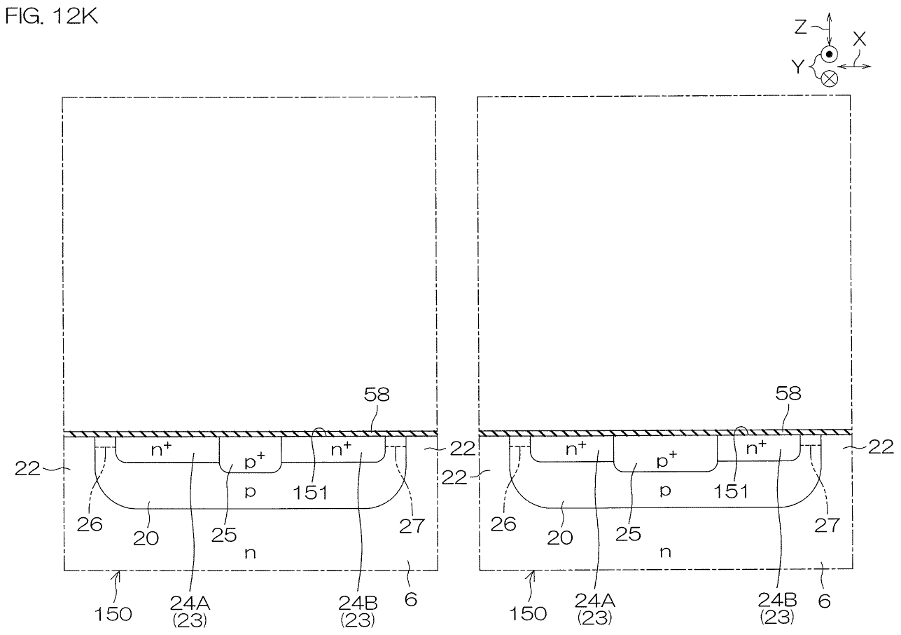

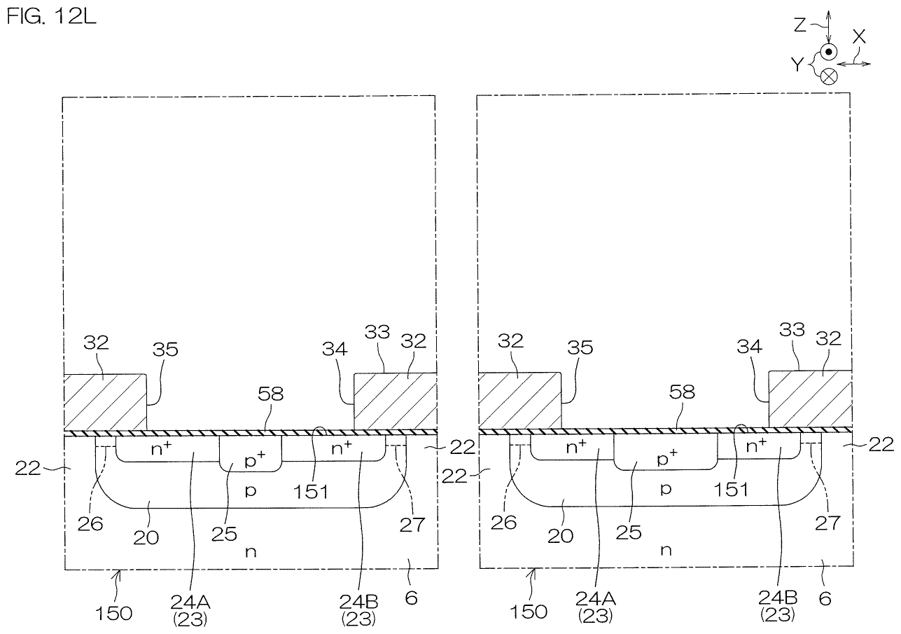

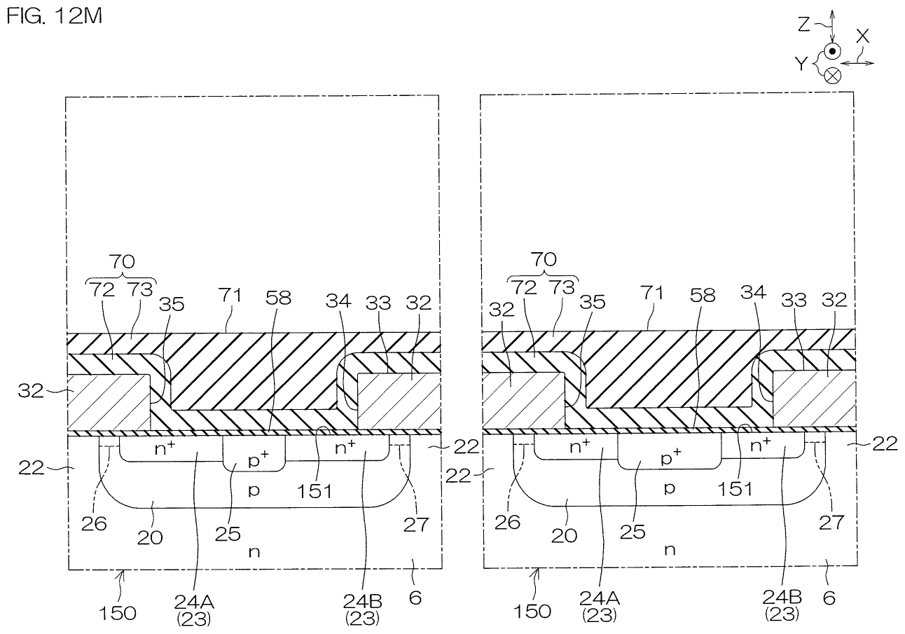

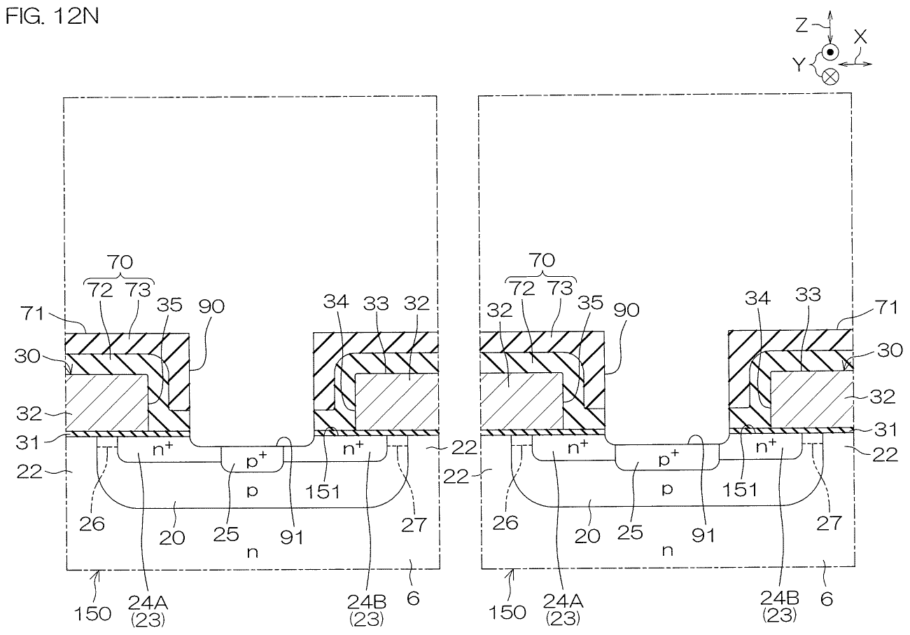

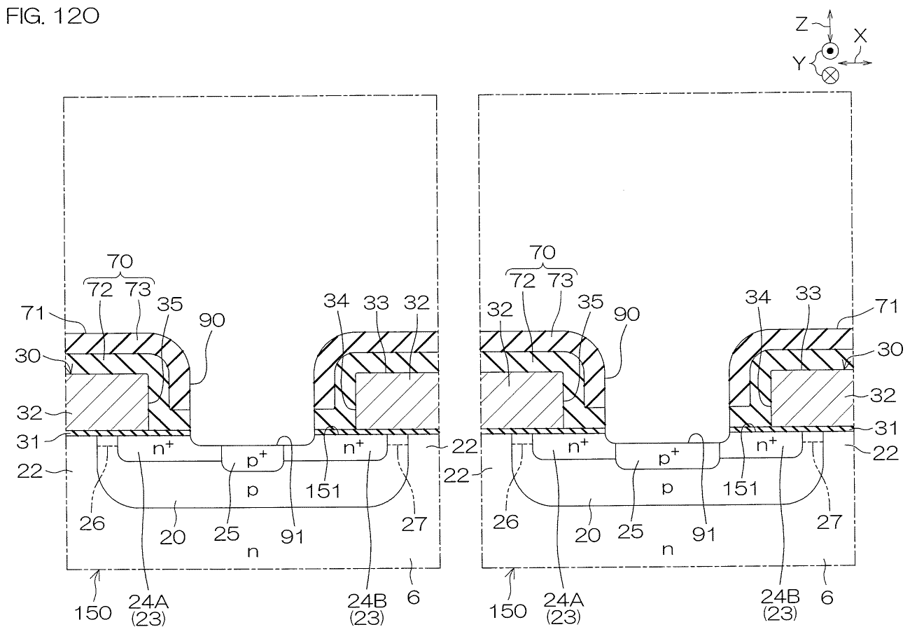

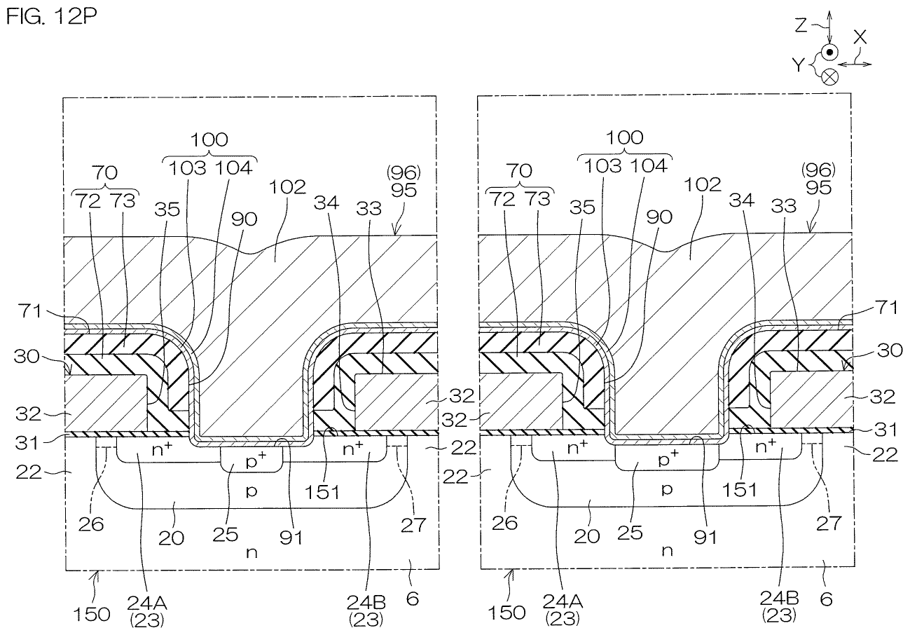

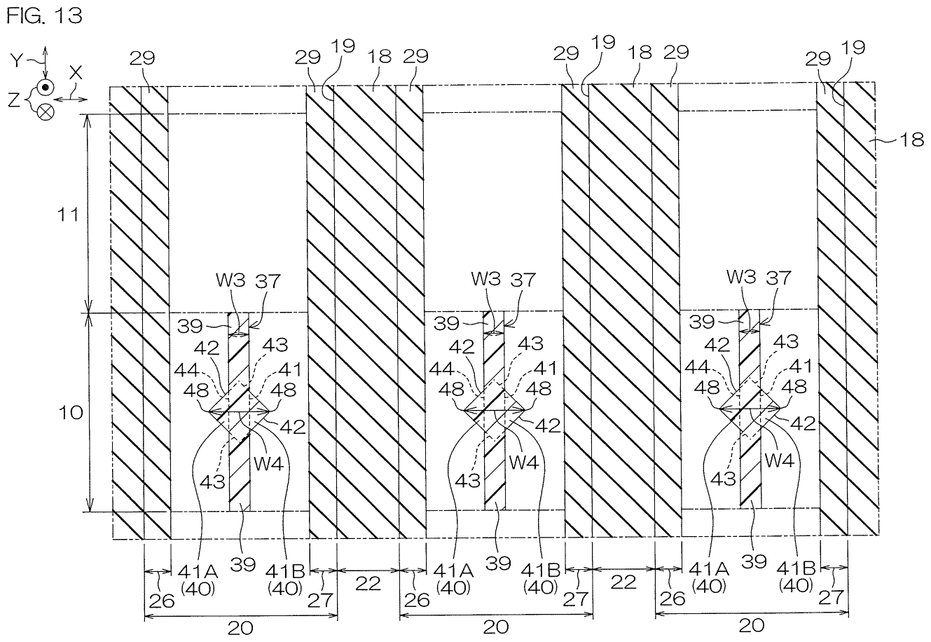

FIGS. 12A to 12P are cross-sectional views illustrating a method for manufacturing the semiconductor device 1. In FIGS. 12A to 12P, a cross-section of a portion of the active region 8 of one device region 155 is shown. In FIGS. 12A to 12P, the left view corresponds to a part of the cross-section of FIG. 7, and the right view corresponds to a part of the cross-section of FIG. 8. FIG. 13 is a view illustrating a planar pattern of a first mask 37 illustrated in FIG. 12G.

Referring to FIG. 12A, first, the above-described wafer 150 is prepared. Next, referring to FIG. 12B, a base mask 18 is formed on the first wafer principal surface 151. The base mask 18 is preferably an inorganic mask (that is, a hard mask). The base mask 18 may include at least one among a silicon oxide film, a silicon nitride film, and a silicon oxynitride film. In this embodiment, the base mask 18 is constituted of a silicon oxide film (insulating film). The base mask 18 may be formed by a CVD method. Next, the base mask 18 is patterned to form a base opening 19. The base opening 19 selectively exposes a region of the first wafer principal surface 151 where the body region 20 and the outer body region 21 (not illustrated) are to be formed.

Next, referring to FIG. 12C, a p-type impurity is selectively introduced into a surface layer portion of the first wafer principal surface 151 by an ion implantation method through the base mask 18, and the plurality of body regions 20 are formed. In addition, a p-type impurity is selectively introduced into the surface layer portion of the first wafer principal surface 151 by the ion implantation method through the base mask 18, and the outer body region 21 is formed.

Next, referring to FIG. 12D, a side wall insulating film 28 is formed on the first wafer principal surface 151 such as to cover the base mask 18 and the body region 20. The side wall insulating film 28 is preferably an inorganic mask (that is, a hard mask). The side wall insulating film 28 may include at least one among a silicon oxide film, a silicon nitride film, and a silicon oxynitride film. In this embodiment, the side wall insulating film 28 is constituted of a silicon oxide film (insulating film). The side wall insulating film 28 may be formed by the CVD method.

Next, referring to FIG. 12E, the side wall insulating film 28 is etched back. Etch-back is continued until front surfaces of the base mask 18 and the body region 20 are exposed. As a result, a portion of the side wall insulating film 28 in contact with a side portion of the base mask 18 selectively remains to form a side wall 29. The side wall 29 covers a peripheral edge portion of each body region 20. Portions of the body region 20 covered with the side wall 29 are a plurality of channel regions 26 and 27. A width WB of an exposed region of the body region 20 sandwiched between the adjacent side walls 29 may be, for example, 4 μm or more and 10 μm or less.

Next, referring to FIG. 12F, a mask material 36 covering the side wall 29 and the base mask 18 is formed such as to backfill the base opening 19 of the base mask 18. The mask material 36 may be an organic material. The mask material 36 may include a positive type or negative type photosensitive resin film (that is, a resist film) as an organic material. As a matter of course, the mask material 36 may be an inorganic material (for example, a silicon oxide film, a silicon nitride film, a polysilicon film, etc.).

Next, referring to FIG. 12G, the mask material 36 is patterned to form the first mask 37. The first mask 37 has a first opening 38 that exposes a region where the source region 23 (the first source region 24A and the second source region 24B) is to be formed.

Here, referring to FIG. 13, the first mask 37 matches the planar shape of the contact region 25. The first mask 37 includes a first portion 39 extending in a band shape in the second direction Y and a plurality of projection portions 40 protruding outward in the first direction X from the first portion 39.

The first portion 39 crosses the first section 10 of the body region 20 in the second direction Y, and has an end portion at the boundary position between the first section 10 and the second section 11. The first portion 39 may be referred to by another name according to its planar shape. For example, as illustrated in FIG. 13, when a shape assumed by excluding the projection portion 40 (a shape in which portions vertically facing each other across the projection portion 40 in the second direction Y are connected by a broken line 44) is a band shape in plan view, the first portion 39 may be referred to as a band-shaped portion. A width (third width W3) of the first portion 39 may be, for example, 0.2 μm or more and 0.6 μm or less.

In this embodiment, the plurality of projection portions 40 may include a pair of projection portions 41A and 41B protruding from the center of the first portion 39 in the second direction Y toward both sides in the first direction X. That is, one projection portion 40 is formed on each of one side and the other side of the first portion 39 in the first direction X. In this embodiment, the projection portion 40 protruding toward the channel region 26 is a first projection portion 41A, and the projection portion 40 protruding toward the channel region 27 is a second projection portion 41B. The first projection portion 41A and the second projection portion 41B protrude from the same position of the first portion 39 toward the opposite sides.

Each of the projection portions 41A and 41B may have a polygonal shape in plan view protruding with respect to the first portion 39 and having one or a plurality of apex portions 48. In this embodiment, each of the projection portions 41A and 41B is formed in a triangular shape in plan view. In the first mask 37, the apex portion 48 has a sharp pointed shape.

The pair of projection portions 41A and 41B may have an overall shape of a rhombus or a circle that protrudes evenly toward both sides with respect to the first portion 39 in plan view. The overall shape of the pair of projection portions 41A and 41B may be a shape defined by an outline 42 of the pair of projection portions 41A and 41B and an inner extension line 43 (virtual line) of the outline 42 toward the inner side of the contact region 25 (first portion 39). FIG. 13 illustrates a pattern in which the overall shape of the pair of projection portions 41A and 41B is a rhombus. In this embodiment, an overall width (fourth width W4) of the pair of projection portions 41A and 41B from an end portion of the first projection portion 41A in the first direction X to an end portion of the second projection portion 41B in the first direction X may be 1.2 μm or more and 1.6 μm or less.

In addition, an aspect ratio (a height H of the first mask 37/the third width W3) in the first portion 39 of the first mask 37 may be 5 or more and 25 or less. An aspect ratio (the height H of the first mask 37/the fourth width W4) of a portion of the first mask 37 where the pair of projection portions 41A and 41B are formed may be 0.8 or more and 4.8 or less.

Next, referring to FIG. 12H, an n-type impurity is selectively introduced into the surface layer portion of the body region 20 by the ion implantation method through the first mask 37 to form the source region 23. In addition, a contact pattern region 50 constituted of a part of the body region 20 covered with the first mask 37 is formed. After the source region 23 is formed, the first mask 37 is removed.

Next, referring to FIG. 12I, a mask material covering the side wall 29 and the base mask 18 is formed. The mask material may be an organic material. The mask material may include a positive type or negative type photosensitive resin film (that is, a resist film) as an organic material. As a matter of course, the mask material may be an inorganic material (for example, a silicon oxide film, a silicon nitride film, a polysilicon film, etc.). Next, the mask material is patterned to form a second mask 56. The second mask 56 has a second opening 57 that exposes a region where the contact region 25 is to be formed.

Next, referring to FIG. 12J, a p-type impurity is selectively introduced into the surface layer portion of the body region 20 by the ion implantation method through the second mask 56 to form the contact region 25. The contact region 25 is formed in the same planar pattern as the first mask 37. However, a slight pattern shift may occur due to an error, etc., in the ion incident angle when the p-type impurity is introduced. Therefore, the apex portion 49 of the pair of projection portions 14A and 14B of the contact region 25 may have a round shape unlike the apex portion 48 of the pair of projection portions 41A and 41B of the first mask 37 (see FIG. 6).

Next, referring to FIG. 12K, a base insulating film 58 covering the first wafer principal surface 151 is formed. The base insulating film 58 is a base of the insulating film 31 and the outer peripheral insulating film 51. The base insulating film 58 may be formed by the CVD (chemical vapor deposition) method or an oxidation treatment method (for example, a thermal oxidation treatment method).

Next, referring to FIG. 12L, a base electrode is formed on the base insulating film 58. The base electrode is a base of the gate electrode 32 and the gate wiring 52. The base electrode contains a conductive polysilicon. The base electrode may be formed by the CVD method. Next, the base electrode is patterned to form the gate electrode 32 and the gate wiring 52.

Next, referring to FIG. 12M, the interlayer film 70 is formed on the first wafer principal surface 151. In this step, the interlayer film 70 having a portion directly covering the electrode surface 33, the first side wall 34, and the second side wall 35 of the gate electrode 32 is formed. In this embodiment, the interlayer film 70 has a laminated structure including the first oxide film 72 and the second oxide film 73. The first oxide film 72 includes a silicon oxide film that is not doped with an impurity. The second oxide film 73 includes a silicon oxide film containing phosphorus. The first oxide film 72 may be formed by the CVD method. The second oxide film 73 may be formed by the CVD method. After the step of forming the second oxide film 73, a reflow step (heat treatment step) is performed on the interlayer film 70. As a result, corner portions and front surface roughness of the interlayer film 70 are smoothed.

Next, referring to FIG. 12N, a mask having a predetermined layout is disposed on the interlayer film 70. The mask exposes regions where the plurality of source openings 90, the plurality of outer openings 92, and the plurality of gate openings 94 are to be formed, and covers regions other than them. Next, an unnecessary portion of the interlayer film 70 and an unnecessary portion of the base insulating film 58 are removed by an etching method through the mask.

In this step, an unnecessary portion of the second oxide film 73, an unnecessary portion of the first oxide film 72, and an unnecessary portion of the base insulating film 58 are removed in this order. The etching method may be a wet etching method and/or a dry etching method. The etching method is preferably an anisotropic dry etching method (for example, an RIE (reactive ion etching) method). As a result, the plurality of source openings 90, the plurality of outer openings 92, and the plurality of gate openings 94 are formed in the interlayer film 70. In addition, the insulating film 31 and the outer peripheral insulating film 51 are formed. This step may include a step of forming the plurality of source recesses 91 and a step of forming the plurality of outer recesses 93. In this case, a step of further digging portions of the first wafer principal surface 151 exposed from the plurality of source openings 90 and the plurality of outer openings 92 toward the second wafer principal surface 152 is performed. The mask is thereafter removed.

Next, referring to FIG. 12O, a surface curved toward the obliquely upper part of the gate electrode 32 is formed at an upper corner portion of the interlayer film 70 by a reflow process. A reflow condition is not particularly limited as long as the reflow condition is such that the upper corner portion of the interlayer film 70 that is pointed after etching in FIG. 12N becomes arcuate. For example, it may be appropriately determined according to the film thickness and film quality of the interlayer film 70, the opening width of the source opening 90, etc.

Next, referring to FIG. 12P, the first base electrode film 100 and the second base electrode film 120 are formed on the interlayer film 70. The first base electrode film 100 and the second base electrode film 120 may be formed by a sputtering method or a vapor deposition method. Next, the first principal electrode film 102 and the second principal electrode film 122 are formed on the first base electrode film 100 and the second base electrode film 120, respectively. The first principal electrode film 102 and the second principal electrode film 122 may include at least one among an Al film, an Al alloy film, a Cu film, and a Cu alloy film. The Al alloy film may include at least one among an AlSi alloy film, an AlCu alloy film, and an AlSiCu alloy film. The first principal electrode film 102 and the second principal electrode film 122 may be formed by the sputtering method or the vapor deposition method.

Thereafter, the drain pad electrode 140 is formed on the second wafer principal surface 152. The drain pad electrode 140 may be formed by the sputtering method or the vapor deposition method. Then, the wafer 150 is cut along the intended cutting line 156, and the plurality of semiconductor devices 1 are cut out. The semiconductor device 1 is manufactured through the steps including the above.

For example, the plurality of gate structures 30 may be arranged at a narrow pitch in order to meet a demand for size reduction of a device. Since a distance between the adjacent gate structures 30 is reduced, formation regions of the source region 23 and the contact region 25 are also reduced. Therefore, installation areas of the first mask 37 and the second mask 56 when the source region 23 and the contact region 25 are formed are reduced.

In particular, referring to FIG. 12G, since the first mask 37 is formed away from the base mask 18, the side wall 29, etc., there is no support in a lateral direction. Therefore, durability against an external force is decreased, and it becomes easy to fall or tilt due to its own weight or an external force. On the other hand, according to the above-described method, as illustrated in FIG. 13, the first mask 37 has the pair of projection portions 41A and 41B, and is partially formed to be wide. Since durability (strength) against an external force can be improved by the pair of projection portions 41A and 41B, it is possible to prevent the first mask 37 from falling or tilting. As a result, the source region 23 and the contact region 25 can be accurately formed even in a fine pattern.

In addition, the chip 2 is a wide bandgap semiconductor (SiC in this embodiment). The wide bandgap semiconductor has a low diffusion coefficient of implanted impurity ions. Therefore, when an impurity region is formed in the lower direction of the wafer 150, a method using high acceleration implantation is adopted instead of thermal diffusion adopted for Si, etc. In order to prevent impurity ions accelerated with high energy from penetrating through the mask (resist) and being implanted, it is necessary to make the mask thicker. For example, in this embodiment, the first mask 37 is thickened in order to prevent the n-type impurity from penetrating through the first mask 37 and being implanted into the contact pattern region 50 when the source region 23 is formed. Specifically, in the first portion 39 of the first mask 37, the aspect ratio (the height H of the first mask 37/the third width W3) is set to 5 or more and 25 or less. With such a high aspect ratio, there is a significant concern about falling or tilting of the first mask 37. However, such a concern can be eliminated by the presence of the pair of projection portions 41A and 41B.

On the other hand, it can be considered that the source region 23 is formed by implanting an n-type impurity into an entire region sandwiched by the side walls 29 while omitting the steps of FIGS. 12G and 12H. Thereafter, a p-type impurity may be implanted into the source region 23 through the second mask 56 supported from the side by the side wall 29 to form the contact region 25. However, it is necessary to form the contact region 25 by implanting a p-type impurity with an excessive concentration capable of canceling the n-type of the source region 23 previously formed, and a front surface state of the first wafer principal surface 151 may be deteriorated (for example, the front surface is roughened.) due to excessive implantation of impurity ions, and a function of the semiconductor device 1 may be deteriorated. For example, contact resistance between the source pad electrode 95 and the contact region 25 may increase due to front surface roughness. On the other hand, in the method described above, since the ion implantation only needs to be performed once for each impurity region, the front surface state of the first wafer principal surface 151 can be maintained in a favorable state.

Although preferred embodiments of the present disclosure have been described above, the present disclosure can be implemented in yet other preferred embodiments.

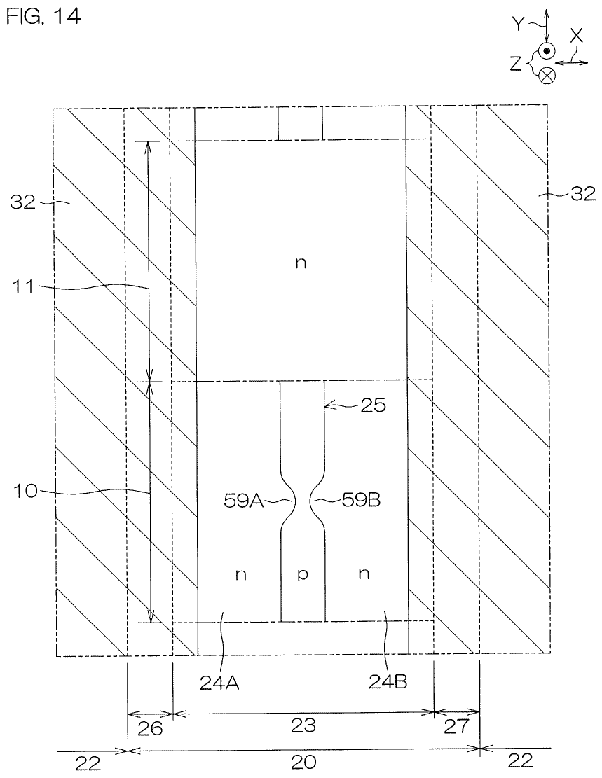

For example, in the above-described preferred embodiment, the contact region 25 is partially formed to be wide and the pair of projection portions 14A and 14B are formed, but as illustrated in FIG. 14, the first source region 24A and the second source region 24B may be partially formed to be wide. In this case, a pair of projection portions 59A and 59B respectively protruding from the first source region 24A and the second source region 24B toward the inside of the contact region 25 may be formed. Further, a structure similar to the pair of projection portions 14A and 14B may be applied to a fine impurity region formed in the chip 2 regardless of the function thereof. For example, it may be applied to the plurality of field regions 47 formed in the outer peripheral region 9.

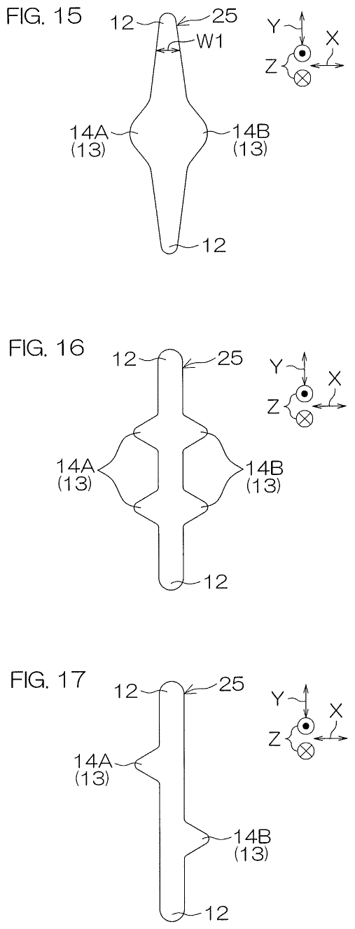

In addition, patterns illustrated in FIGS. 15 to 19 may be adopted as the modification pattern of the contact region 25. In FIG. 15, the first width W1 of the first portion 12 of the contact region 25 gradually narrows from the pair of projection portions 14A and 14B toward an end portion in the second direction Y. Thus, the first portion 12 may be formed in a substantially tapered shape in plan view.

In FIG. 16, the plurality of projection portions 14A and 14B are formed on one side and the other side of the first portion 12 of the contact region 25 in the first direction X, respectively. In FIG. 17, the pair of projection portions 14A and 14B protrudes toward the opposite sides from different positions of the first portion 12 in the second direction Y.

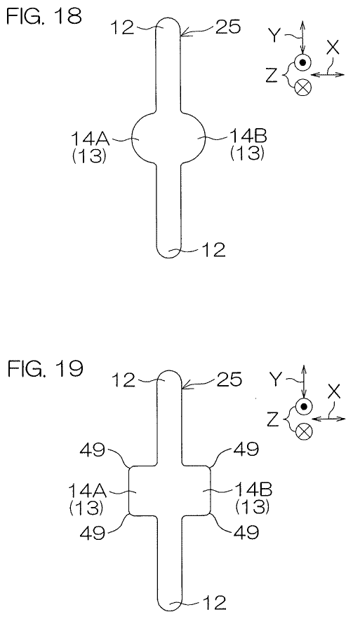

In FIG. 18, each of the projection portions 14A and 14B is formed in a semicircular shape in plan view. In FIG. 19, each of the projection portions 14A and 14B is formed in a quadrangular shape in plan view. In this case, the corner portions (apex portions 49) of the quadrangle may have a rounded round shape.

For example, in each of the above-described preferred embodiments, a configuration in which a relationship between the a-axis direction and the m-axis direction is interchanged may be adopted. A specific configuration in this case can be obtained by interchanging the “a-axis direction (off direction)” and the “m-axis direction (direction orthogonal to off direction)” in the above description and the accompanying drawings.

In each of the above-described preferred embodiments, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above descriptions and the accompanying drawings.

In each of the above-described preferred embodiments, the chip 2 (the first semiconductor region 6 and the second semiconductor region 7) containing an SiC monocrystal is adopted. However, the chip 2 (the first semiconductor region 6 and the second semiconductor region 7) may include a monocrystal of a wide bandgap semiconductor other than the SiC monocrystal. The wide bandgap semiconductor is a semiconductor having a bandgap greater than a bandgap of silicon. Examples of the monocrystal of the wide bandgap semiconductor include gallium nitride, diamond, gallium oxide, etc. As a matter of course, the chip 2 (the first semiconductor region 6 and the second semiconductor region 7) may contain a silicon monocrystal.

In each of the above-described preferred embodiments, the second semiconductor region 7 of the n-type has been illustrated. However, the p-type second semiconductor region 7 may be adopted instead of the n-type second semiconductor region 7. In this case, an IGBT (insulated gate bipolar transistor) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The second semiconductor region 7 of the p-type may be an impurity region that contains a p-type impurity introduced into a surface layer portion of the second principal surface 4 of the chip 2 by the ion implantation method.

Hereinafter, examples of features extracted from this description and the attached drawings shall be indicated. Hereinafter, the alphanumeric characters, etc., in parentheses represent the corresponding components, etc., in the preferred embodiments described above, but are not intended to limit the scope of each clause to the preferred embodiments. The “semiconductor device” in the following clauses may be replaced with an “SiC semiconductor device,” a “wide bandgap semiconductor device,” a “semiconductor switching device,” a “MISFET device,” an “IGBT device,” etc., as needed.
[Appendix 1-1]

A semiconductor device (1) including:
a chip (2) formed by a wide bandgap semiconductor and having a principal surface on which a semiconductor region (6) of a first conductivity type is formed;
a base impurity region (20) of a second conductivity type formed in a surface layer portion of the semiconductor region (6);
a first impurity region (13, 25) formed in a surface layer portion of the base impurity region (20); and
a second impurity region (25, 13) of a conductivity type opposite to that of the first impurity region (13, 25) formed in the surface layer portion of the base impurity region (20), the second impurity region (25, 13) being adjacent to the first impurity region (13, 25) in a first direction (X),
wherein the second impurity region (25, 13) is formed in a band shape extending in a second direction (Y) orthogonal to the first direction (X), and includes a projection portion (13) selectively protruding toward the first impurity region (13, 25) in the first direction (X).
[Appendix 1-2]

The semiconductor device (1) according to Appendix 1-1, wherein
the second impurity region (25, 13) is sandwiched between the first impurity regions (13, 25) from both sides in the first direction (X), and
a pair of the projection portions (14A, 14B) protrude toward opposite sides in the first direction (X).
[Appendix 1-3]

The semiconductor device (1) according to Appendix 1-2, wherein the second impurity region (25, 13) includes a first portion (12) extending in the second direction (Y) and having a first width (W1) in the first direction (X), and the pair of the projection portions (14A, 14B) protruding from a center of the first portion (12) in the second direction (Y) toward the both sides in the first direction (X).
[Appendix 1-4]

The semiconductor device (1) according to Appendix 1-3, wherein the pair of the projection portions (14A, 14B) have an overall shape of a rhombus or a circle that protrudes evenly toward the both sides with respect to the first portion (12) in plan view.
[Appendix 1-5]

The semiconductor device (1) according to Appendix 1-3 or Appendix 1-4, wherein
the first width (W1) of the first portion (12) is 0.2 μm or more and 0.6 μm or less, and
an overall second width (W2) of the pair of the projection portions (14A, 14B) from an end portion of the one projection portion (13) to an end portion of the other projection portion (13) is 1.2 μm or more and 1.6 μm or less.
[Appendix 1-6]

The semiconductor device (1) according to Appendix 1-5, wherein a width (WS) of the first impurity region (13, 25) in the first direction (X) is larger than the second width (W2) of the pair of the projection portions (14A, 14B).
[Appendix 1-7]

The semiconductor device (1) according to Appendix 1-1, including:
a body region (20) as the base impurity region (20) formed in the surface layer portion of the semiconductor region (6);
the first impurity region (13) formed in a surface layer portion of the body region (20);
a body contact region (25) as the second impurity region (25) formed in the surface layer portion of the body region (20), penetrating through the first impurity region (13), and connected to the body region (20);
a channel (26, 27) formed in a region between the semiconductor region (6) and the first impurity region (13) in the surface layer portion of the body region (20); and
a gate electrode (32) formed on the channel (26, 27) across an insulating film (31).
[Appendix 1-8]

The semiconductor device (1) according to Appendix 1-7, wherein
the plurality of body regions (20) are arranged in a stripe shape extending in the second direction (Y),
each of the body regions (20) has a plurality of first sections (10) and a plurality of second sections (11) alternately in the second direction (Y), and
the plurality of body contact regions (25) are arranged at intervals for each of the first sections (10) such as to skip each of the second sections (11) in the second direction (Y).
[Appendix 1-9]

The semiconductor device (1) according to Appendix 1-8, wherein the body contact region (25) includes a first portion (12) crossing the first section (10) in the second direction (Y) and having a first width (W1) in the first direction (X), and the pair of the projection portions (14A, 14B) protruding from a center of the first portion (12) in the second direction (Y) toward the both sides in the first direction (X).
[Appendix 1-10]

The semiconductor device (1) according to Appendix 1-9, wherein the pair of the projection portions (14A, 14B) have an overall shape of a rhombus or a circle that protrudes evenly toward the both sides with respect to the first portion (12) in plan view.
[Appendix 1-11]

The semiconductor device (1) according to Appendix 1-10, wherein
the first width (W1) of the first portion (12) is 0.2 μm or more and 0.6 μm or less, and
an overall second width (W2) of the pair of the projection portions (14A, 14B) from an end portion of the one projection portion (14A) to an end portion of the other projection portion (14B) is 1.2 μm or more and 1.6 μm or less.
[Appendix 1-12]

The semiconductor device (1) according to Appendix 1-11, wherein a width (WS) of the first impurity region (13) in the first direction (X) is larger than the second width (W2) of the pair of the projection portions (14A, 14B).
[Appendix 1-13]

The semiconductor device (1) according to Appendix 1-1, including:
a body region (20) as the base impurity region (20) formed in the surface layer portion of the semiconductor region (6);
the second impurity region (13) formed in a surface layer portion of the body region (20);
a body contact region (25) as the first impurity region (25) formed in the surface layer portion of the body region (20), penetrating through the second impurity region (13), and connected to the body region (20);
a channel (26, 27) formed in a region between the semiconductor region (6) and the second impurity region (13) in the surface layer portion of the body region (20); and
a gate electrode (32) formed on the channel (26, 27) across an insulating film (31).
[Appendix 1-14]

The semiconductor device (1) according to Appendix 1-13, wherein
the plurality of body regions (20) are arranged in a stripe shape extending in the second direction (Y),
each of the body regions (20) has a plurality of first sections (10) and a plurality of second sections (11) alternately in the second direction (Y), and
the plurality of body contact regions (25) are arranged at intervals for each of the first sections (10) such as to skip each of the second sections (11) in the second direction (Y).
[Appendix 1-15]

The semiconductor device (1) according to any one of Appendix 1-1 to Appendix 1-14, wherein the chip (2) is an SiC chip.
[Appendix 1-16]

A method for manufacturing a semiconductor device (1) including:
a step of preparing a wafer (150) formed by a wide bandgap semiconductor and having a principal surface (151) on which a semiconductor region (6) of a first conductivity type is formed, and selectively forming a plurality of body regions (20) at intervals in a first direction (X) in a surface layer portion of the semiconductor region (6) by selectively implanting a second conductivity type impurity into the semiconductor region (6);
a step of forming a first mask (37) that selectively covers each of the body regions (20), wherein the first mask (37) includes a first portion (39) extending in a second direction (Y) orthogonal to the first direction (X) and having a first width (W3) in the first direction (X), and the pair of the projection portions (41A, 41B) protruding from a center of the first portion (39) in the second direction (Y) toward both sides in the first direction (X);
a step of forming a first impurity region (13) in a surface layer portion of the body region (20) by implanting a first conductivity type impurity into the body region (20) through the first mask (37), and leaving a contact pattern region (50) constituted of a part of the body region (20) in a region covered with the first mask (37);
a step of forming a second mask (56) that has an opening (57) for selectively exposing the contact pattern region (50) and covers the first impurity region (13);
a step of forming a body contact region (25) in the surface layer portion of the body region (20) by implanting a second conductivity type impurity into the contact pattern region (50) through the second mask (56); and
a step of forming a gate electrode (32) covering a channel (26, 27) formed in a region between the semiconductor region (6) and the first impurity region (13) in the surface layer portion of the body region (20).
[Appendix 1-17]

The method for manufacturing a semiconductor device (1) according to Appendix 1-16, further including:
a step of forming, on the principal surface (151), a hard mask (18) selectively having an opening (19) in a region where the body region (20) is to be formed;
a step of forming a side wall (29) on a side portion of the hard mask (18) to cover a region where the channel (26, 27) is to be formed after the body region (20) is formed by implantation of the second conductivity type impurity through the hard mask (18),
a step of forming a mask material (36) covering the side wall (29) and the hard mask (18) such as to backfill the opening in the hard mask (18); and
a step of forming the first mask (37) by patterning the mask material (36).
[Appendix 1-18]

The method for manufacturing a semiconductor device (1) according to Appendix 1-16 or Appendix 1-17, wherein an aspect ratio (a height (H) of the first portion (39)/the width (W3) of the first portion (39)) in the first portion (12) of the first mask (37) is 5 or more and 25 or less.

1. A semiconductor device comprising:
a chip formed by a wide bandgap semiconductor and having a principal surface on which a semiconductor region of a first conductivity type is formed;
a base impurity region of a second conductivity type formed in a surface layer portion of the semiconductor region;
a first impurity region formed in a surface layer portion of the base impurity region; and
a second impurity region of a conductivity type opposite to that of the first impurity region formed in the surface layer portion of the base impurity region, the second impurity region being adjacent to the first impurity region in a first direction,
wherein the second impurity region is formed in a band shape extending in a second direction orthogonal to the first direction, and includes a projection portion selectively protruding toward the first impurity region in the first direction.

2. The semiconductor device according to claim 1, wherein
the second impurity region is sandwiched between the first impurity regions from both sides in the first direction, and
a pair of the projection portions protrude toward opposite sides in the first direction.

3. The semiconductor device according to claim 2, wherein the second impurity region includes a first portion extending in the second direction and having a first width in the first direction, and the pair of the projection portions protruding from a center of the first portion in the second direction toward the both sides in the first direction.

4. The semiconductor device according to claim 3, wherein the pair of the projection portions have an overall shape of a rhombus or a circle that protrudes evenly toward the both sides with respect to the first portion in plan view.

5. The semiconductor device according to claim 3, wherein
the first width of the first portion is 0.2 μm or more and 0.6 μm or less, and
an overall second width of the pair of the projection portions from an end portion of the one projection portion to an end portion of the other projection portion is 1.2 μm or more and 1.6 μm or less.

6. The semiconductor device according to claim 5, wherein a width of the first impurity region in the first direction is larger than the second width of the pair of the projection portions.

7. The semiconductor device according to claim 1, comprising:
a body region as the base impurity region formed in the surface layer portion of the semiconductor region;
the first impurity region formed in a surface layer portion of the body region;
a body contact region as the second impurity region formed in the surface layer portion of the body region, penetrating through the first impurity region, and connected to the body region;
a channel formed in a region between the semiconductor region and the first impurity region in the surface layer portion of the body region; and
a gate electrode formed on the channel across an insulating film.

8. The semiconductor device according to claim 7, wherein
the plurality of body regions are arranged in a stripe shape extending in the second direction,
each of the body regions has a plurality of first sections and a plurality of second sections alternately in the second direction, and
the plurality of body contact regions are arranged at intervals for each of the first sections such as to skip each of the second sections in the second direction.

9. The semiconductor device according to claim 8, wherein the body contact region includes a first portion crossing the first section in the second direction and having a first width in the first direction, and the pair of the projection portions protruding from a center of the first portion in the second direction toward the both sides in the first direction.

10. The semiconductor device according to claim 9, wherein the pair of the projection portions have an overall shape of a rhombus or a circle that protrudes evenly toward the both sides with respect to the first portion in plan view.

11. The semiconductor device according to claim 10, wherein
the first width of the first portion is 0.2 μm or more and 0.6 μm or less, and
an overall second width of the pair of the projection portions from an end portion of the one projection portion to an end portion of the other projection portion is 1.2 μm or more and 1.6 μm or less.

12. The semiconductor device according to claim 11, wherein a width of the first impurity region in the first direction is larger than the second width of the pair of the projection portions.

13. The semiconductor device according to claim 1, comprising:
a body region as the base impurity region formed in the surface layer portion of the semiconductor region;
the second impurity region formed in a surface layer portion of the body region;
a body contact region as the first impurity region formed in the surface layer portion of the body region, penetrating through the second impurity region, and connected to the body region;
a channel formed in a region between the semiconductor region and the second impurity region in the surface layer portion of the body region; and
a gate electrode formed on the channel across an insulating film.

14. The semiconductor device according to claim 13, wherein
the plurality of body regions are arranged in a stripe shape extending in the second direction,
each of the body regions has a plurality of first sections and a plurality of second sections alternately in the second direction, and
the plurality of body contact regions are arranged at intervals for each of the first sections such as to skip each of the second sections in the second direction.

15. The semiconductor device according to claim 1, wherein the chip is an SiC chip.

16. A method for manufacturing a semiconductor device comprising:
a step of preparing a wafer formed by a wide bandgap semiconductor and having a principal surface on which a semiconductor region of a first conductivity type is formed, and selectively forming a plurality of body regions at intervals in a first direction in a surface layer portion of the semiconductor region by selectively implanting a second conductivity type impurity into the semiconductor region;
a step of forming a first mask that selectively covers each of the body regions, wherein the first mask includes a first portion extending in a second direction orthogonal to the first direction and having a first width in the first direction, and the pair of the projection portions protruding from a center of the first portion in the second direction toward both sides in the first direction;
a step of forming a first impurity region in a surface layer portion of the body region by implanting a first conductivity type impurity into the body region through the first mask, and leaving a contact pattern region constituted of a part of the body region in a region covered with the first mask;
a step of forming a second mask that has an opening for selectively exposing the contact pattern region and covers the first impurity region;
a step of forming a body contact region in the surface layer portion of the body region by implanting a second conductivity type impurity into the contact pattern region through the second mask; and
a step of forming a gate electrode covering a channel formed in a region between the semiconductor region and the first impurity region in the surface layer portion of the body region.

17. The method for manufacturing a semiconductor device according to claim 16, further comprising:
a step of forming, on the principal surface, a hard mask selectively having an opening in a region where the body region is to be formed;
a step of forming a side wall on a side portion of the hard mask to cover a region where the channel is to be formed after the body region is formed by implantation of the second conductivity type impurity through the hard mask;
a step of forming a mask material covering the side wall and the hard mask such as to backfill the opening in the hard mask; and
a step of forming the first mask by patterning the mask material.

18. The method for manufacturing a semiconductor device according to claim 16, wherein an aspect ratio (a height of the first portion/the width of the first portion) in the first portion of the first mask is 5 or more and 25 or less.
